(19) United States
(12) Patent Application Publication
(10) Pub. No.: US 2024/0006402 A1
(43) Pub. Date: Jan. 4, 2024

(54) SEMICONDUCTOR DEVICE

(71) Applicant: ROHM CO., LTD., Kyoto-shi (JP)

(72) Inventor: Masashi HAYASHIGUCHI, Kyoto-shi (JP)

(21) Appl. No.: 18/466,470

(22) Filed: Sep. 13, 2023

Related U.S. Application Data
(63) Continuation of application No. PCT/JP2022/019512, filed on May 2, 2022.

(30) Foreign Application Priority Data
May 13, 2021 (JP) 2021-081623

(51) Int. Cl. H01L 25/18; H01L 23/495; H01L 23/64; H01L 23/00

(52) U.S. Cl. CPC H01L 25/18; H01L 23/49562; H01L 23/645; H01L 24/32; H01L 24/40; H01L 24/73; H01L 2224/32227; H01L 2224/32238; H01L 2224/40229; H01L 2224/48229; H01L 2224/73263; H01L 24/48; H01L 2924/13091; H01L 2924/13055; H01L 2924/12032

(57) ABSTRACT

A semiconductor device includes a first MOSFET and a first IGBT. A drain of the first MOSFET and a collector of the first IGBT are electrically connected to each other. A source of the first MOSFET and an emitter of the first IGBT are electrically connected to each other. An element withstand voltage of the first MOSFET is larger than an element withstand voltage of the first IGBT.

### TECHNICAL FIELD

The present disclosure relates to a semiconductor device.

### BACKGROUND ART

Semiconductor devices with switching elements such as metal oxide semiconductor field effect transistors (MOSFETs) and insulated gate bipolar transistors (IGBTs) are conventionally known. For example, JP-A-2018-174252 discloses a power module (semiconductor device) with switching elements, which are either MOSFETs or IGBTs. Such a power module is used in an inverter, for example, and performs power conversion through switching operations by the switching elements.

### BRIEF DESCRIPTION OF THE DRAWINGS

FIG. 1 is a perspective view showing a semiconductor device according to a first embodiment.

FIG. 2 is a plan view showing the semiconductor device according to the first embodiment, with a sealing member indicated by an imaginary line.

FIG. 3 is a cross-sectional view along line in FIG. 2.

FIG. 4 is a cross-sectional view along line IV-IV in FIG. 2.

FIG. 5 is a cross-sectional view along line V-V in FIG. 2.

FIG. 6 shows an example of the circuit configuration of the semiconductor device according to the first embodiment.

FIG. 7 is a perspective view showing a semiconductor device according to a second embodiment.

FIG. 8 is a view similar to the perspective view of FIG. 7 but omitting a portion (top plate) of a case and a resin member.

FIG. 9 is a plan view showing the semiconductor device according to the second embodiment, with a portion (top plate) of the case and the resin member being omitted.

FIG. 10 is a cross-sectional view along line X-X in FIG. 9.

FIG. 11 is a cross-sectional view along line XI-XI in FIG. 9.

FIG. 12 is a cross-sectional view along line XII-XII in FIG. 9.

FIG. 13 is a cross-sectional view along line XIII-XIII in FIG. 9.

FIG. 14 is a perspective view showing a semiconductor device according to a third embodiment.

FIG. 15 is a plan view showing the semiconductor device according to the third embodiment, with a sealing member indicated by an imaginary line.

FIG. 16 is a view similar to the plan view of FIG. 15 but omitting an obverse-surface metal layer, a plurality of outer terminals, a plurality of connecting members, and a resin member.

FIG. 17 is a view similar to the plan view of FIG. 16 but omitting an insulating substrate.

FIG. 18 is a cross-sectional view along line XVIII-XVIII in FIG. 15.

FIG. 19 is a cross-sectional view along line XIX-XIX in FIG. 15.

FIG. 20 is a perspective view showing a semiconductor device according to a fourth embodiment.

FIG. 21 is a view similar to the perspective view of FIG. 20 but omitting a sealing member.

FIG. 22 is a plan view showing the semiconductor device according to the fourth embodiment, with the sealing member indicated by an imaginary line.

FIG. 23 is a cross-sectional view along line XXIII-XXIII in FIG. 22.

FIG. 24 is a cross-sectional view along line XXIV-XXIV in FIG. 22.

FIG. 25 is a plan view showing a semiconductor device according to a variation, with a sealing member indicated by an imaginary line.

FIG. 26 is a plan view showing a semiconductor device according to a variation, with a sealing member indicated by an imaginary line.

### DETAILED DESCRIPTION OF EMBODIMENTS

The following describes the preferred embodiments of a semiconductor device according to the present disclosure with reference to the accompanying drawings. In the description given below, the same or similar elements are denoted by the same reference signs, and the descriptions thereof are omitted. In the present disclosure, the terms “first”, “second”, “third” etc., are used merely as labels and are not necessarily intended to impose orders on the items to which these terms refer.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located an object B with another object interposed between the object A and the object B”. Furthermore, the phrase “an object A overlaps with an object B as viewed in a certain direction” includes, unless otherwise specified, “an object A overlaps with the entirety of an object B” and “an object A overlaps with a portion of an object B”.

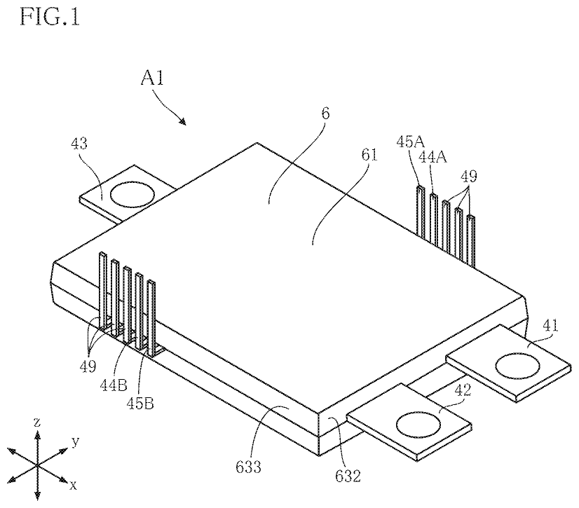

FIGS. 1 to 6 show a semiconductor device A1 according to a first embodiment. The semiconductor device A1 includes two switching circuits 1 and 2, a supporting member 3, a plurality of outer terminals, a plurality of connecting members, and a sealing member 6. The outer terminals include a plurality of power terminals 41, 42, and 43, and a plurality of signal terminals 44A, 44B, 45A, 45B, and 49. The connecting members include a plurality of power connecting members 511 to 513, and 521 to 523, and a plurality of signal connecting members 541A, 541B, 542A, 542B, 551A, 551B, 552A, and 552B.

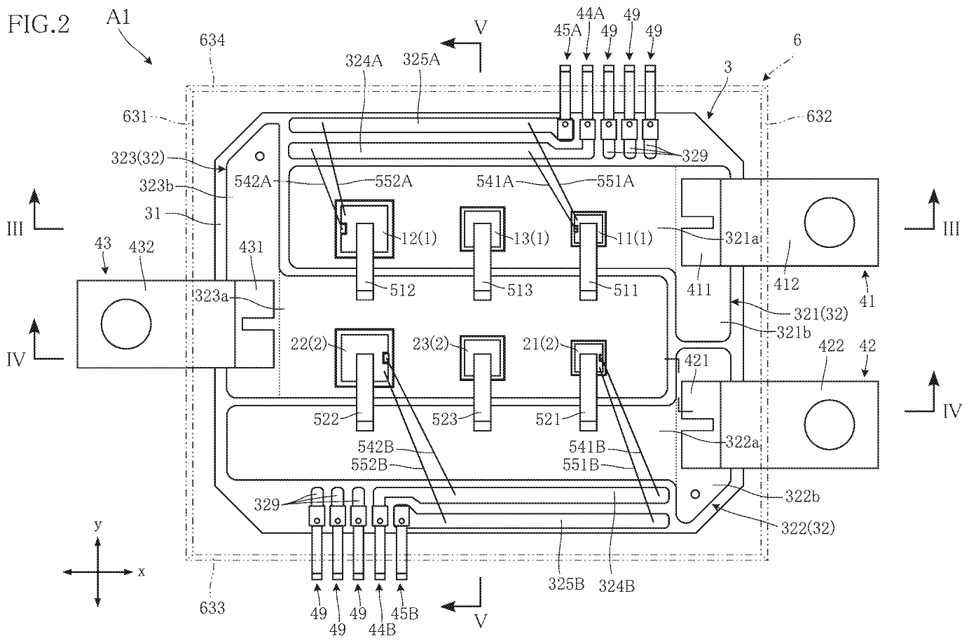

For convenience, three mutually perpendicular directions are referred to as a first direction x, a second direction y, and a third direction z, respectively. The third direction z corresponds to the thickness direction of the semiconductor device A1. The first direction x corresponds to the horizontal direction in a plan view (see FIG. 2) of the semiconductor device A1. The second direction y corresponds to the vertical direction in a plan view (see FIG. 2) of the semiconductor device A1.

The two switching circuits 1 and 2 perform electrical functions of the semiconductor device A1. Each of the two switching circuits 1 and 2 is controlled by a drive circuit arranged outside the semiconductor device A1, and switches between a connected state and a disconnected state. The switching between the connected state and the disconnected state is referred to as a switching operation. For example, the two switching circuits 1 and 2 convert an inputted source voltage (DC voltage) into an AC voltage through their respective switching operations. Note that the source voltage may be an AC voltage instead of a DC voltage, and the converted voltage may be a DC voltage instead of an AC voltage. The main current in the semiconductor device A1 is generated by the source voltage and the converted voltage.

The switching circuit 1 includes a MOSFET 11 as a first MOSFET, an IGBT 12 as a first IGBT, and a Schottky barrier diode (hereinafter “SBD”) 13 as a first Schottky barrier diode. The MOSFET 11 comprises a first semiconductor material, for example. The IGBT 12 comprises a second semiconductor material, for example. The SBD 13 comprises a third semiconductor material, for example. Each of the first semiconductor material, the second semiconductor material, and the third semiconductor material is either silicon (Si), silicon carbide (SiC), gallium arsenide (GaAs), gallium nitride (GaN) or Ga₂O₃ (gallium oxide), for example. It is preferable that the first semiconductor material and the third semiconductor material have a wider band gap than the second semiconductor material. In the semiconductor device A1, each of the MOSFET 11 and the SBD 13 may comprise SiC, and the IGBT 12 may comprise Si.

The MOSFET 11 has an obverse surface 11a and a reverse surface 11b. The obverse surface 11a and the reverse surface 11b are spaced apart from each other in the thickness direction of the MOSFET 11. In the semiconductor device A1, the MOSFET 11 is arranged such that the thickness direction of the MOSFET 11 coincides (or substantially coincides) with the third direction z. The MOSFET 11 has a vertical structure, where a drain 111 is arranged on the reverse surface 11b, and where a source 112 and a gate 113 are arranged on the obverse surface 11a. The switching operation of the MOSFET 11 is controlled by a first drive signal (e.g., gate voltage) inputted to the gate 113. The MOSFET 11 has a rectangular shape, for example, as viewed in the third direction z (hereinafter, also referred to as “plan view”).

The IGBT 12 has an obverse surface 12a and a reverse surface 12b. The obverse surface 12a and the reverse surface 12b are spaced apart from each other in the thickness direction of the IGBT 12. In the semiconductor device A1, the IGBT 12 is arranged such that the thickness direction of the IGBT 12 coincides (or substantially coincides) with the third direction z. The IGBT 12 has a vertical structure, where a collector 121 is arranged on the reverse surface 12b, and where an emitter 122 and a gate 123 are arranged on the obverse surface 12a. The switching operation of the IGBT 12 is controlled by a first drive signal (e.g., gate voltage) inputted to the gate 123. The IGBT 12 has a rectangular shape in plan view, for example. In the semiconductor device A1, the MOSFET 11 and the IGBT 12 receive a common first drive signal.

The SBD 13 has an obverse surface 13a and a reverse surface 13b. The obverse surface 13a and the reverse surface 13b are spaced apart from each other in the thickness direction of the SBD 13. In the semiconductor device A1, the SBD 13 is arranged such that the thickness direction of the SBD 13 coincides (or substantially coincides) with the third direction z. The SBD 13 has a cathode 132 and an anode 131, with the cathode 132 arranged on the obverse surface 13a and the anode 131 arranged on the reverse surface 13b. The SBD 13 has a rectangular shape in plan view, for example.

In the switching circuit 1, the element withstand voltage of the MOSFET 11 (drain withstand voltage) is larger than the element withstand voltage of the IGBT 12 (collector withstand voltage). For example, in the case where the source voltage (DC voltage) is between 400 V and 500 V, the element withstand voltage of the MOSFET 11 is 750 V, and the element withstand voltage of the IGBT 12 is 650 V. In the switching circuit 1, the area of the MOSFET 11 is smaller than the area of the IGBT 12 in plan view, and the area of the SBD 13 is larger than the area of the MOSFET 11 and smaller than the area of the IGBT 12 in plan view. The relationship between the plan view areas of the MOSFET 11, the IGBT 12, and the SBD 13 is not limited to the above example.

The switching circuit 1 has a configuration described in detail below, whereby the drain 111 of the MOSFET 11, the collector 121 of the IGBT 12, and the cathode 132 of the SBD 13 are electrically connected to each other, and the source 112 of the MOSFET 11, the emitter 122 of the IGBT 12, and the anode 131 of the SBD 13 are electrically connected to each other. As a result, the MOSFET 11 and the IGBT 12 are electrically connected in parallel to each other, whereas the SBD 13 is electrically connected in reverse parallel to the MOSFET 11 and the IGBT 12. When one of the MOSFET 11 and the IGBT 12 is in a connected state, the switching circuit 1 is in a connected state. When the MOSFET 11 and the IGBT 12 are both in a disconnected state, the switching circuit 1 is in a disconnected state. The switching operations of the MOSFET 11 and the IGBT 12 cause the switching circuit 1 to perform a switching operation.

The switching circuit 2 includes a MOSFET 21 as a second MOSFET, an IGBT 22 as a second IGBT, and an SBD 23 as a second Schottky barrier diode. As with the MOSFET 11, the MOSFET 21 comprises a first semiconductor material, for example. As with the IGBT 12, the IGBT 22 comprises a second semiconductor material, for example. As with the SBD 13, the SBD 23 comprises a third semiconductor material, for example. In the semiconductor device A1, each of the MOSFET 21 and the SBD 23 may comprise SiC, and the IGBT 22 may comprise Si.

The MOSFET 21 has an obverse surface 21a and a reverse surface 21b. The obverse surface 21a and the reverse surface 21b are spaced apart from each other in the thickness direction of the MOSFET 21. In the semiconductor device A1, the MOSFET 21 is arranged such that the thickness direction of the MOSFET 21 coincides (or substantially coincides) with the third direction z. The MOSFET 21 has a vertical structure, where a drain 211 is arranged on the reverse surface 21b and a source 212 and a gate 213 are arranged on the obverse surface 21a. The switching operation of the MOSFET 21 is controlled by a second drive signal (e.g., gate voltage) inputted to the gate 213. The MOSFET 21 has a rectangular shape in plan view, for example.

The IGBT 22 has an obverse surface 22a and a reverse surface 22b. The obverse surface 22a and the reverse surface 22b are spaced apart from each other in the thickness direction of the IGBT 22. In the semiconductor device A1, the IGBT 22 is arranged such that the thickness direction of the IGBT 22 coincides (or substantially coincides) with the third direction z. The IGBT 22 has a vertical structure, where a collector 221 is arranged on the reverse surface 22b, and where an emitter 222 and a gate 223 are arranged on the obverse surface 22a. The switching operation of the IGBT 22 is controlled by a second drive signal (e.g., gate voltage) inputted to the gate 223. The IGBT 22 has a rectangular shape in plan view, for example. In the semiconductor device A1, the MOSFET 21 and the IGBT 22 receive a common second drive signal.

The SBD 23 has an obverse surface 23a and a reverse surface 23b. The obverse surface 23a and the reverse surface 23b are spaced apart from each other in the thickness direction of the SBD 23. In the semiconductor device A1, the SBD 23 is arranged such that the thickness direction of the SBD 23 coincides (or substantially coincides) with the third direction z. The SBD 23 has a cathode 232 and an anode 231, with the cathode 232 arranged on the obverse surface 23a and the anode 231 arranged on the reverse surface 23b. The SBD 23 has a rectangular shape in plan view, for example.

In the switching circuit 2, the element withstand voltage of the MOSFET 21 (drain withstand voltage) is larger than the element withstand voltage of the IGBT 22 (collector withstand voltage). For example, in the case where the source voltage (DC voltage) is between 400 V and 500 V, the element withstand voltage of the MOSFET 21 is 750 V, and the element withstand voltage of the IGBT 22 is 650 V. In the switching circuit 2, the area of the MOSFET 21 is smaller than the area of the IGBT 22 in plan view, and the area of the SBD 23 is larger than the area of the MOSFET 21 and smaller than the area of the IGBT 22 in plan view. The relationship between the plan view areas of the MOSFET 21, the IGBT 22, and the SBD 23 is not limited to the above example.

The switching circuit 2 has a configuration described in detail below, whereby the drain 211 of the MOSFET 21, the collector 221 of the IGBT 22, and the cathode 232 of the SBD 23 are electrically connected to each other, and the source 212 of the MOSFET 21, the emitter 222 of the IGBT 22, the anode 231 of the SBD 23 are electrically connected to each other. As a result, the MOSFET 21 and the IGBT 22 are electrically connected in parallel to each other, whereas the SBD 23 is electrically connected in reverse parallel to the MOSFET 21 and the IGBT 22. When one of the MOSFET 21 and the IGBT 22 is in a connected state, the switching circuit 2 is in a connected state. When the MOSFET 21 and the IGBT 22 are both in a disconnected state, the switching circuit 2 is in a disconnected state. The switching operations of the MOSFET 21 and the IGBT 22 cause the switching circuit 2 to perform a switching operation.

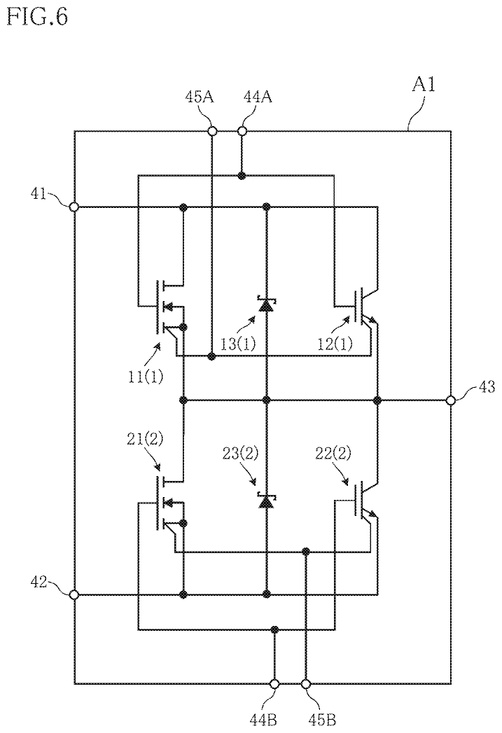

As shown in FIG. 6, the semiconductor device A1 is configured as a half-bridge circuit, for example. The switching circuit 1 and the switching circuit 2 are connected in series. Specifically, the source 112 of the MOSFET 11, the emitter 122 of the IGBT 12, and the anode 131 of the SBD 13 are electrically connected to the drain 211 of the MOSFET 21, the collector 221 of the IGBT 22, and the cathode 232 of the SBD 23. The switching circuit 1 constitutes an upper arm circuit of the semiconductor device A1, and the switching circuit 2 constitutes a lower arm circuit of the semiconductor device A1.

The supporting member 3 supports the two switching circuits 1 and 2, and forms a conduction path connecting the two switching circuits 1 and 2 to the power terminals 41-43 and the signal terminals 44A, 44B, 45A, 45B, and 49. The supporting member 3 has an insulating substrate 31, an obverse-surface metal layer 32, and a reverse-surface metal layer 33.

The insulating substrate 31 is made of a ceramic with excellent thermal conductivity, for example. The ceramic may be aluminum nitride (AlN), silicon nitride (SiN), or aluminum oxide (Al₂O₃). The insulating substrate 31 is in the form of a flat plate, for example.

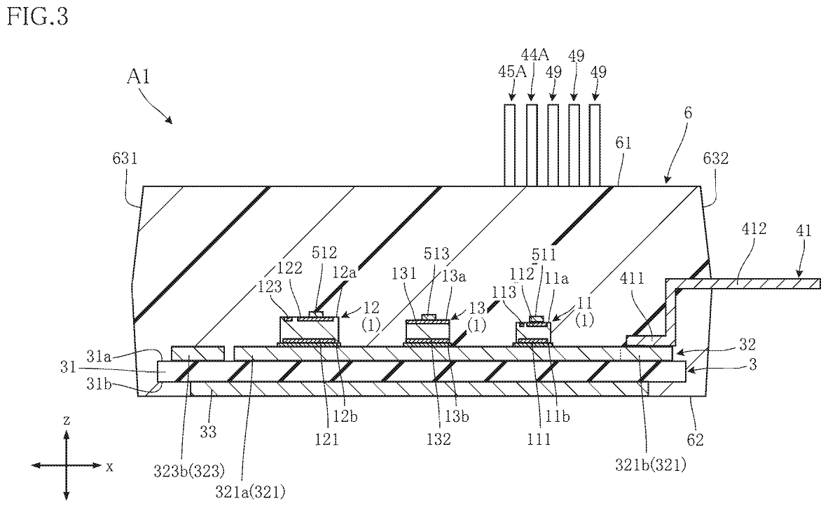

The insulating substrate 31 has an obverse surface 31a and a reverse surface 31b. The obverse surface 31a and the reverse surface 31b are spaced apart from each other in the third direction z. As shown in FIG. 3, the obverse surface 31a faces in one sense of the third direction z (upward), and the reverse surface 31b faces in the other sense of the third direction z (downward).

The obverse-surface metal layer 32 is formed on the obverse surface 31a of the insulating substrate 31. The constituent material of the obverse-surface metal layer 32 is copper or a copper alloy, for example. The constituent material may be aluminum or an aluminum alloy instead of copper or a copper alloy. The obverse-surface metal layer 32 is covered with the sealing member 6. The obverse-surface metal layer 32 includes a power wiring section 321 as a first conductor, a power wiring section 322 as a third conductor, a power wiring section 323 as a second conductor, and a plurality of signal wiring sections 324A, 324B, 325A, 325B, and 329. The power wiring sections 321, 322, and 323 are spaced apart from the signal wiring sections 324A, 324B, 325A, 325B, and 329.

The power wiring section 321 includes two pad portions 321a and 321b. The two pad portions 321a and 321b are formed integrally with each other.

The MOSFET 11, the IGBT 12, and the SBD 13 are mounted on the pad portion 321a. In the example shown in FIGS. 2 and 3, the MOSFET 11, the SBD 13, and the IGBT 12 are arranged on the pad portion 321a in the stated order in the first direction x. In other words, the direction in which the MOSFET 11, the IGBT 12, and the SBD 13 are arranged (hereinafter “first arrangement direction”) coincides (or substantially coincides) with the first direction x. In the example shown in FIGS. 2 and 3, the MOSFET 11 is offset from the IGBT 12 in one sense of the first direction x (i.e., toward the power terminals 41 and 42). The drain 111 of the MOSFET 11, the collector 121 of the IGBT 12, and the cathode 132 of the SBD 13 are electrically bonded to the pad portion 321a via a conductive bonding member (e.g., solder, a metal paste material, or a sintered metal). With this configuration, the drain 111 of the MOSFET 11, the collector 121 of the IGBT 12, and the cathode 132 of the SBD 13 are electrically connected to each other. For example, the pad portion 321a has a rectangular shape elongated in the first direction x in plan view.

The power terminal 41 is bonded to the pad portion 321b. For example, the pad portion 321b has a strip shape extending in the second direction y in plan view. The pad portion 321a extends from the pad portion 321b in the first direction x. The power wiring section 322 includes two pad portions 322a and 322b. The two pad portions 322a and 322b are formed integrally with each other.

The power connecting members 521, 522, and 523 are bonded to the pad portion 322a. The pad portion 322a is electrically connected to the source 212 of the MOSFET 21, the emitter 222 of the IGBT 22, and the anode 231 of the SBD 23 via the power connecting members 521, 522, and 523. For example, the pad portion 322a has a rectangular shape elongated in the first direction x in plan view.

The power terminal 42 is bonded to the pad portion 322b. For example, the pad portion 322b has a strip shape extending in the second direction y in plan view. The pad portion 322a extends from the pad portion 322b in the first direction x.

The power wiring section 323 includes two pad portions 323a and 323b. The two pad portions 323a and 323b are formed integrally with each other.

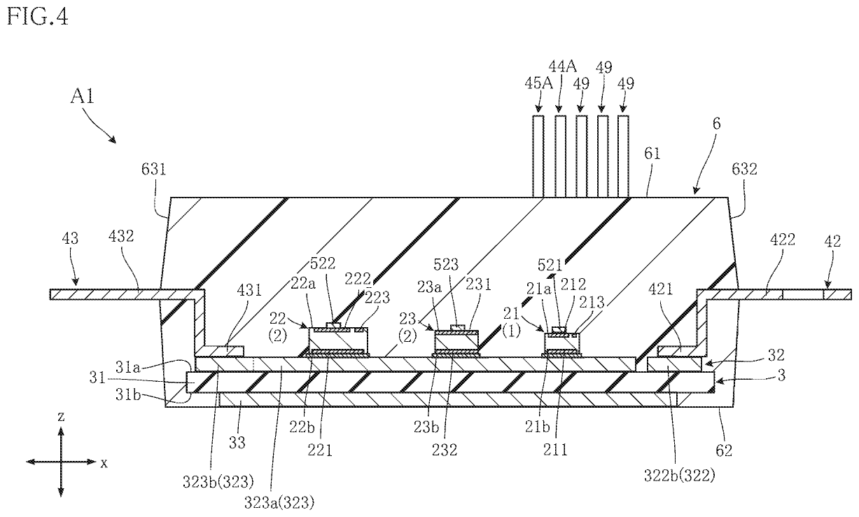

The MOSFET 21, the IGBT 22, and the SBD 23 are mounted on the pad portion 323a. In the example shown in FIGS. 2 and 4, the MOSFET 21, the SBD 23, and the IGBT 22 are arranged on the pad portion 323a in the stated order in the first direction x. In other words, the direction in which the MOSFET 21, the IGBT 22, and the SBD 23 are arranged (hereinafter “second arrangement direction”) coincides (or substantially coincides) with the first direction x and the first arrangement direction. In the example shown in FIGS. 2 and 4, the MOSFET 21 is offset from the IGBT 22 in one sense of the first direction x (i.e., toward the power terminals 41 and 42). The drain 211 of the MOSFET 21, the collector 221 of the IGBT 22, and the cathode 232 of the SBD 23 are electrically bonded to the pad portion 323a via a conductive bonding member (e.g., solder, a metal paste material, or a sintered metal). With this configuration, the drain 211 of the MOSFET 21, the collector 221 of the IGBT 22, and the cathode 232 of the SBD 23 are electrically connected to each other. The power connecting members 511, 512, and 513 are bonded to the pad portion 323a. The pad portion 323a is electrically connected to the source 112 of the MOSFET 11, the emitter 122 of the IGBT 12, and the anode 131 of the SBD 13 via the power connecting members 511, 512, and 513. For example, the pad portion 323a has a rectangular shape elongated in the first direction x in plan view.

The power terminal 43 is bonded to the pad portion 323b. For example, the pad portion 323b has a strip shape extending in the second direction y in plan view. The pad portion 323a extends from the pad portion 323b in the first direction x.

In the semiconductor device A1, the three pad portions 321a, 322a, and 323a are arranged in the second direction y and in parallel (or substantially parallel) in plan view. The pad portion 323a is located between the pad portion 321a and the pad portion 322a in the second direction y.

The two signal connecting members 541A and 542A are connected to the signal wiring section 324A. The signal wiring section 324A is electrically connected to the gate 113 of the MOSFET 11 via the signal connecting member 541A. The signal wiring section 324A is also electrically connected to the gate 123 of the IGBT 12 via the signal connecting member 542A. The signal wiring section 324A transmits the first drive signal for controlling the switching operations of the switching circuit 1 (the switching operation of the MOSFET 11 and the switching operation of the IGBT 12).

The two signal connecting members 541B and 542B are connected to the signal wiring section 324B. The signal wiring section 324B is electrically connected to the gate 213 of the MOSFET 21 via the signal connecting member 541B. The signal wiring section 324B is also electrically connected to the gate 223 of the IGBT 22 via the signal connecting member 542B. The signal wiring section 324B transmits the second drive signal for controlling the switching operations of the switching circuit 2 (the switching operation of the MOSFET 21 and the switching operation of the IGBT 22).

The two signal connecting members 551A and 552A are connected to the signal wiring section 325A. The signal wiring section 325A is electrically connected to the source 112 of the MOSFET 11 via the signal connecting member 551A. The signal wiring section 325A is also electrically connected to the emitter 122 of the IGBT 12 via the signal connecting member 552A. The signal wiring section 325A transmits a first detection signal indicating the connected state of the switching circuit 1. The voltage of each of the source 112 of the MOSFET 11 and the emitter 122 of the IGBT 12 is applied to the signal wiring section 325A.

The two signal connecting members 551B and 552B are connected to the signal wiring section 325B. The signal wiring section 325B is electrically connected to the source 212 of the MOSFET 21 via the signal connecting member 551B. The signal wiring section 325B is also electrically connected to the emitter 222 of the IGBT 22 via the signal connecting member 552B. The signal wiring section 325B transmits a second detection signal indicating the connected state of the switching circuit 2. The voltage of each of the source 212 of the MOSFET 21 and the emitter 222 of the IGBT 22 is applied to the signal wiring section 325B.

The signal wiring sections 329 are not electrically connected to either of the two switching circuits 1 and 2 (the two MOSFETs 11, 21, the two IGBTs 12, 22, and the two SBDs 13, 23). In other words, neither the main current nor electric signals flow through the signal wiring sections 329.

The reverse-surface metal layer 33 is formed on the reverse surface 31b of the insulating substrate 31. The reverse-surface metal layer 33 is made of the same constituent material as the obverse-surface metal layer 32. The reverse-surface metal layer 33 has a surface facing downward in the third direction z and exposed from the sealing member 6. Note that the surface of the reverse-surface metal layer 33 facing downward in the third direction z may be covered with the sealing member 6. Furthermore, the supporting member 3 may not include the reverse-surface metal layer 33. In this case, the reverse surface 31b of the insulating substrate 31 may be covered with the sealing member 6, or may be exposed from the sealing member 6.

The outer terminals include the power terminal 41 as a first power terminal, the power terminal 42 as a third power terminal, the power terminal 43 as a second power terminal, and the signal terminals 44A, 44B, 45A, 45B, and 49. A portion of each of the power terminals 41 to 43 and the signal terminals 44A, 44B, 45A, 45B, and 49 is exposed from the sealing member 6. The power terminals 41 to 43 and the signal terminals 44A, 44B, 45A, 45B, and 49 are bonded to the obverse-surface metal layer 32 within the sealing member 6. The power terminals 41 to 43 and the signal terminals 44A, 44B, 45A, 45B, and 49 are formed from the same lead frame, are each a metal plate. The constituent material of each of the power terminals 41 to 43 and the signal terminals 44A, 44B, 45A, 45B, and 49 is copper or a copper alloy, for example. The power terminal 41 is electrically connected to the drain 111 of the MOSFET 11, the collector 121 of the IGBT 12, and the cathode 132 of the SBD 13. The power terminal 41 includes a bonding portion 411 and a terminal portion 412.

As shown in FIGS. 2 and 3, the bonding portion 411 is covered with the sealing member 6. As shown in FIGS. 2 and 3, the bonding portion 411 is bonded to the pad portion 321b of the power wiring section 321. As a result, the power terminal 41 is electrically connected to the power wiring section 321. Bonding between the bonding portion 411 and the pad portion 321b may be achieved by any of bonding with a conductive bonding member (e.g., solder or a sintered metal), laser bonding, or ultrasonic bonding.

As shown in FIGS. 2 and 3, the terminal portion 412 is exposed from the sealing member 6. As shown in FIG. 2, the terminal portion 412 extends from the sealing member 6 in one sense of the first direction x in plan view. The surface of the terminal portion 412 may be plated with silver, for example.

The power terminal 42 is electrically connected to the source 212 of the MOSFET 21, the emitter 222 of the IGBT 22, and the anode 231 of the SBD 23. The power terminal 42 includes a bonding portion 421 and a terminal portion 422.

As shown in FIGS. 2 and 4, the bonding portion 421 is covered with the sealing member 6. As shown in FIGS. 2 and 4, the bonding portion 421 is bonded to the pad portion 322b of the power wiring section 322. As a result, the power terminal 42 is electrically connected to the power wiring section 322. Bonding between the bonding portion 421 and the pad portion 322b may be achieved by any of bonding with a conductive bonding member (e.g., solder or a sintered metal), laser bonding, or ultrasonic bonding.

As shown in FIGS. 2 and 4, the terminal portion 422 is exposed from the sealing member 6. As shown in FIG. 2, the terminal portion 422 extends from the sealing member 6 in one sense of the first direction x in plan view. The surface of the terminal portion 422 may be plated with silver, for example.

The power terminal 43 is electrically connected to the source 112 of the MOSFET 11, the emitter 122 of the IGBT 12, and the anode 131 of the SBD 13, as well as to the drain 211 of the MOSFET 21, the collector 221 of the IGBT 22, and the cathode 232 of the SBD 23. The power terminal 43 includes a bonding portion 431 and a terminal portion 432.

As shown in FIGS. 2 and 4, the bonding portion 431 is covered with the sealing member 6. As shown in FIGS. 2 and 4, the bonding portion 431 is bonded to the pad portion 323b of the power wiring section 323. As a result, the power terminal 43 is electrically connected to the power wiring section 323. Bonding between the bonding portion 431 and the pad portion 323b may be achieved by any of bonding with a conductive bonding member (e.g., solder or a sintered metal), laser bonding, or ultrasonic bonding.

As shown in FIGS. 2 and 4, the terminal portion 432 is exposed from the sealing member 6. As shown in FIG. 2, the terminal portion 432 extends from the sealing member 6 in the other sense of the first direction x in plan view. The surface of the terminal portion 432 may be plated with silver, for example.

In the semiconductor device A1, the power terminal 41 and the power terminal 42 are connected to a power source that applies the above-described source voltage (e.g., DC voltage) to the power terminals 41 and 42. For example, the power terminal 41 is a positive electrode (P terminal), and the power terminal 42 is a negative electrode (N terminal). The power terminal 41 and the power terminal 42 are spaced apart from each other and arranged in the second direction y. The power terminal 43 outputs the voltage (e.g., AC voltage) converted by the switching operations of the switching circuit 1 and the switching circuit 2. The power terminal 43 is a power output terminal (OUT terminal), for example.

In the semiconductor device A1, the power terminal 41 and the power terminal 42 are arranged on one side of the supporting member 3 in the first direction x, and the power terminal 43 is arranged on the other side of the supporting member 3 in the first direction x. In the semiconductor device A1, the power terminal 41 and the power terminal 42 are located opposite from the IGBTs 12 and 22 with respect to the MOSFETs 11 and 21 in the first direction x.

As shown in FIG. 2, the signal terminal 44A is bonded to the signal wiring section 324A. The signal terminal 44A is electrically connected to the gate 113 of the MOSFET 11 and the gate 123 of the IGBT 12, via the signal wiring section 324A and the signal connecting members 541A and 542A. The signal terminal 44A is an input terminal for the first drive signal, and may be connected to an external drive circuit, for example.

As shown in FIG. 2, the signal terminal 44B is bonded to the signal wiring section 324B. The signal terminal 44B is electrically connected to the gate 213 of the MOSFET 21 and the gate 223 of the IGBT 22, via the signal wiring section 324B and the signal connecting members 541B and 542B. The signal terminal 44B is an input terminal for the second drive signal, and may be connected to an external drive circuit, for example.

As shown in FIG. 2, the signal terminal 45A is bonded to the signal wiring section 325A. The signal terminal 45A is electrically bonded to the source 112 of the MOSFET 11 and the emitter 122 of the IGBT 12, via the signal wiring section 325A and the signal connecting members 551A and 552A. The signal terminal 45A is an output terminal for the first detection signal, and may be connected to the external drive circuit, for example.

As shown in FIG. 2, the signal terminal 45B is bonded to the signal wiring section 325B. The signal terminal 45B is electrically bonded to the source 212 of the MOSFET 21 and the emitter 222 of the IGBT 22, via the signal wiring section 325B and the signal connecting members 551B and 552B. The signal terminal 45B is an output terminal for the second detection signal, and may be connected to the external drive circuit, for example.

As shown in FIG. 2, the signal terminals 49 are bonded to the respective signal wiring sections 329. None of the signal terminals 49 is connected to either of the two switching circuits 1 and 2. Each of the signal terminals 49 is a non-connected terminal.

Each of the connecting members electrically connect the two elements that are spaced apart from each other. The connecting members include the power connecting member 511 as a first connecting member, the power connecting member 512 as a second connecting member, the power connecting member 513, the power connecting member 521 as a third connecting member, the power connecting member 522 as a fourth connecting member, the power connecting member 523, and the signal connecting members 541A, 541B, 542A, 542B, 551A, 551B, 552A, and 552B.

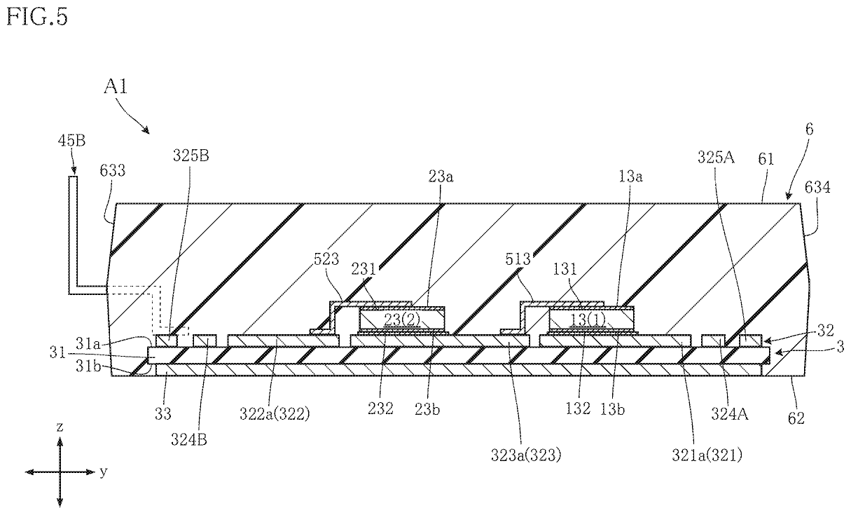

Each of the power connecting members 511 to 513, and 521 to 523 is a conduction path for the main current. Each of the power connecting members 511 to 513, and 521 to 523 is formed from a metallic flat plate, for example. Each of the power connecting members 511 to 513, and 521 to 523 may be one or more bonding wires instead of a metallic flat plate. The constituent material of each of the power connecting members 511 to 513, and 521 to 523 is copper or a copper alloy, for example. The constituent material may be gold, a gold alloy, aluminum, or an aluminum alloy instead of copper or a copper alloy. As shown in FIG. 5, a portion of each of the power connecting members 513 and 523 is bent. As with the power connecting members 513 and 523, each of the power connecting members 511, 512, 521, and 522 is partially bent.

The power connecting member 511 is connected to the source 112 of the MOSFET 11 and the pad portion 323a so as to electrically connect the source 112 and the power wiring section 323. The power connecting member 512 is connected to the emitter 122 of the IGBT 12 and the pad portion 323a so as to electrically connect the emitter 122 and the power wiring section 323. The power connecting member 513 is connected to the anode 131 of the SBD 13 and the pad portion 323a so as to electrically connect the anode 131 and the power wiring section 323. With this configuration, the source 112 of the MOSFET 11, the emitter 122 of the IGBT 12, and the anode 131 of the SBD 13 are electrically connected.

The power connecting member 521 is connected to the source 212 of the MOSFET 21 and the pad portion 322a so as to electrically connect the source 212 and the power wiring section 322. The power connecting member 522 is connected to the emitter 222 of the IGBT 22 and the pad portion 322a so as to electrically connect the emitter 222 and the power wiring section 322. The power connecting member 523 is connected to the anode 231 of the SBD 23 and the pad portion 322a so as to electrically connect the anode 231 and the power wiring section 322. With this configuration, the source 212 of the MOSFET 21, the emitter 222 of the IGBT 22, and the anode 231 of the SBD 23 are electrically connected.

Each of the signal connecting members 541A, 541B, 542A, 542B, 551A, 551B, 552A, and 552B is a conduction path for an electric signal. Each of the signal connecting members 541A, 541B, 542A, 542B, 551A, 551B, 552A, and 552B is a bonding wire, for example. The constituent material of each of the signal connecting members 541A, 541B, 542A, 542B, 551A, 551B, 552A, and 552B is gold or a gold alloy, for example. The constituent material may be copper, a copper alloy, aluminum, or an aluminum alloy instead of gold or a gold alloy.

The signal connecting member 541A is connected to the gate 113 of the MOSFET 11 and the signal wiring section 324A so as to electrically connect the gate 113 and the signal wiring section 324A. The signal connecting member 542A is connected to the gate 123 of the IGBT 12 and the signal wiring section 324A so as to electrically connect the gate 123 and the signal wiring section 324A.

The signal connecting member 541B is connected to the gate 213 of the MOSFET 21 and the signal wiring section 324B so as to electrically connect the gate 213 and the signal wiring section 324B. The signal connecting member 542B is connected to the gate 223 of the IGBT 22 and the signal wiring section 324B so as to electrically connect the gate 223 and the signal wiring section 324B.

The signal connecting member 551A is connected to the source 112 of the MOSFET 11 and the signal wiring section 325A so as to electrically connect the source 112 and the signal wiring section 325A. The signal connecting member 552A is connected to the emitter 122 of the IGBT 12 and the signal wiring section 325A so as to electrically connect the emitter 122 and the signal wiring section 325A.

The signal connecting member 551B is connected to the source 212 of the MOSFET 21 and the signal wiring section 325B so as to electrically connect the source 212 and the signal wiring section 325B. The signal connecting member 552B is connected to the emitter 222 of the IGBT 22 and the signal wiring section 325B so as to electrically connect the emitter 222 and the signal wiring section 325B.

The sealing member 6 protects the two switching circuits 1 and 2, and so on. The sealing member 6 covers the two switching circuits 1 and 2, a portion of the supporting member 3, a portion of each of the power terminals 41, 42, and 43, a portion of each of the signal terminals 44A, 44B, 45A, 45B, and 49, the power connecting members 511 to 513, and 521 to 523, and the signal connecting members 541A, 541B, 542A, 542B, 551A, 551B, 552A, and 552B. The sealing member 6 is made of an insulating resin material, for example. The insulating resin material is epoxy resin, for example. The sealing member 6 has a resin obverse surface 61, a resin reverse surface 62, and a plurality of resin side surfaces 631 to 634.

As shown in FIGS. 3 to 5, the resin obverse surface 61 and the resin reverse surface 62 are spaced apart from each other in the third direction z. The resin obverse surface 61 faces in one sense of the third direction z (upward), and the resin reverse surface 62 faces in the other sense of the third direction z (downward). The resin side surfaces 631 to 634 are located between and connected to the resin obverse surface 61 and the resin reverse surface 62 in the third direction z. The two resin side surfaces 631 and 632 face away from each other in the first direction x. The power terminals 41 and 42 protrude from the resin side surface 632, and the power terminal 43 protrudes from the resin side surface 631. The two resin side surfaces 633 and 634 face away from each other in the second direction y. The signal terminals 44A and 45A protrude from the resin side surface 634, and the signal terminals 44B and 45B protrude from the resin side surface 633.

The following describes the effects and advantages of the semiconductor device A1.

In the semiconductor device A1, the element withstand voltage of the MOSFET 11 is larger than the element withstand voltage of the IGBT 12. As such, when a surge voltage is generated during the switching operation of the switching circuit 1, the surge voltage exceeds the element withstand voltage of the IGBT 12 before exceeding the element withstand voltage of the MOSFET 11. As a result, the IGBT 12 enters an avalanche mode before the MOSFET 11. The avalanche mode is a state in which avalanche breakdown occurs. The research by the present inventor shows that due to the difference in avalanche resistance between the MOSFET 11 and the IGBT 12, the IGBT 12 is less likely to suffer from a chip failure in the case of avalanche mode whereas the MOSFET 11 is more likely to break down in the case of avalanche mode. Accordingly, even if a surge voltage is generated by the switching operation of the switching circuit 1, the IGBT 12 enters an avalanche mode before the MOSFET 11 and absorbs the surge voltage to prevent the MOSFET 11 from entering the avalanche mode. The semiconductor device A1 is configured such that even if a switching surge occurs in the switching circuit 1, the IGBT 12 experiences avalanche breakdown before the MOSFET 11. This makes it possible to reduce failures of the MOSFET 11 and the IGBT 12. In other words, the semiconductor device A1 can reduce failures caused by a surge voltage when the MOSFET 11 and the IGBT 12 perform operations in parallel, and can suppress a decrease in reliability.

For example, in the semiconductor device A1, when the source voltage applied to the two power terminals 41 and 42 is between 400 V and 500 V, a surge voltage of approximately 650 V may be generated by the switching operation of the switching circuit 1. In this case, each of the MOSFET 11 and the IGBT 12 can be designed to have an element withstand voltage of approximately 650 V so as to match the surge voltage. However, according to the semiconductor device A1, the element withstand voltage of the MOSFET 11 is set to 750 V, and the element withstand voltage of the IGBT 12 is set to 650 V. In this way, even if the IGBT 12 enters an avalanche mode, the MOSFET 11 may not enter the avalanche mode. In other words, according to the semiconductor device A1, even if a surge voltage is generated by the switching operation of the switching circuit 1, the IGBT 12 enters an avalanche mode before the MOSFET 11 to reduce failures of the MOSFET 11 and the IGBT 12.

In the semiconductor device A1, the MOSFET 11 comprises SiC, and the IGBT 12 comprises Si. In general, the MOSFET 11 comprising SiC tends to have a lower avalanche resistance than the IGBT 12 comprising Si. Thus, setting an element withstand voltage for each of the MOSFET 11 and the IGBT 12 to achieve the above-described relationship is effective in reducing failures of the MOSFET 11 and the IGBT 12.

In the semiconductor device A1, the inductance of a first conduction path from the power terminal 41 to the drain 111 of the MOSFET 11 is smaller than the inductance of a second conduction path from the power terminal 41 to the collector 121 of the IGBT 12. For example, as can be understood from FIG. 2, the semiconductor device A1 is configured such that the first conduction path is shorter than the second conduction path to thereby make the inductance of the first conduction path smaller than the inductance of the second conduction path. According to this configuration, the inductance of the second conduction path is larger than the inductance of the first conduction path, and as a result, a larger switching surge is generated in the IGBT 12 than in the MOSFET 11. Accordingly, even if a surge voltage is generated by the switching operation of the switching circuit 1, the IGBT 12 enters an avalanche mode before the MOSFET 11 regardless of the relationship between the element withstand voltage of the MOSFET 11 and the element withstand voltage of the IGBT 12. Since the MOSFET 11 can be prevented from entering the avalanche mode by allowing the IGBT 12 to absorb a surge voltage, failures of the MOSFET 11 and the IGBT 12 can be reduced. In other words, the semiconductor device A1 can further reduce failures caused by a surge voltage when the MOSFET 11 and the IGBT 12 perform operations in parallel, and can suppress a decrease in reliability.

In the semiconductor device A1, the MOSFET 11 and the IGBT 12 are mounted on the pad portion 321a, and the pad portion 321a extends in the first arrangement direction of the MOSFET 11 and the IGBT 12 (e.g., first direction x) in in plan view. The pad portion 321a is connected to the pad portion 321b to which the power terminal 41 is bonded, and the pad portion 321b is connected to an edge of the pad portion 321a closer to the MOSFET 11 than to the IGBT 12 in the first arrangement direction. With this configuration, the first conduction path can be shorter than the second conduction path.

The semiconductor device A1 includes the SBD 13. The SBD 13 is connected in reverse parallel to the MOSFET 11 and the IGBT 12. According to this configuration, even if a switching surge is generated by the switching operation of the switching circuit 1, the current that flows through a diode in each of the MOSFET 11 and the IGBT 12 is reduced by the energization of the SBD 13. As such, the semiconductor device A1 can reduce failures of the MOSFET 11 and the IGBT 12 by suppressing a switching surge applied to the MOSFET 11 and the IGBT 12. In other words, even if a switching surge is generated during the switching operations of the MOSFET 11 and the IGBT 12, the semiconductor device A1 can reduce failures caused by the switching surge and suppress a decrease in reliability. In particular, according to the semiconductor device A1, a third conduction path from the power terminal 41 to the SBD 13 is longer than the first conduction path from the power terminal 41 to the MOSFET 11, and is shorter than the second conduction path from the power terminal 41 to the IGBT 12. Such a configuration is effective in reducing a switching surge applied to the MOSFET 11 and the IGBT 12. For example, in the semiconductor device A1, when the power terminal 41 is arranged on one side of the switching circuit 1, the SBD 13 is arranged between the MOSFET 11 and the IGBT 12 in the first arrangement direction. This results in the third conduction path being longer than the first conduction path and shorter than the second conduction path.

In the semiconductor device A1, the element withstand voltage of the MOSFET 21 is larger than the element withstand voltage of the IGBT 22. According to this configuration of the switching circuit 2, as with the switching circuit 1, even if a surge voltage is generated by the switching operation of the switching circuit 2, the IGBT 22 enters an avalanche mode before the MOSFET 21 to reduce failures of the MOSFET 21 and the IGBT 22. In other words, the semiconductor device A1 can reduce failures caused by a surge voltage when the MOSFET 21 and the IGBT 22 perform operations in parallel, and can suppress a decrease in reliability. In the case where the source voltage applied to the two power terminals 41 and 42 is between 400 V and 500 V, the element withstand voltage of the MOSFET 21 in the switching circuit 2 is set to 750 V, and the element withstand voltage of the IGBT 22 is set to 650 V, as with the case of the switching circuit 1. In this way, according to the semiconductor device A1, even if a surge voltage is generated by the switching operation of the switching circuit 2, the IGBT 22 enters an avalanche mode before the MOSFET 21 to reduce failures of the MOSFET 21 and the IGBT 22.

In the semiconductor device A1, the inductance of a fourth conduction path from the power terminal 41 to the drain 211 of the MOSFET 21 is smaller than the inductance of a fifth conduction path from the power terminal 41 to the collector 221 of the IGBT 22. For example, as can be understood from FIG. 2, the semiconductor device A1 is configured such that the fourth conduction path is shorter than the fifth conduction path to thereby make the inductance of the fourth conduction path smaller than the inductance of the fifth conduction path. According to this configuration of the switching circuit 2, as with the switching circuit 1, even if a surge voltage is generated by the switching operation of the switching circuit 2, the IGBT 22 enters an avalanche mode before the MOSFET 21 to reduce failures of the MOSFET 21 and the IGBT 22. In other words, the semiconductor device A1 can further reduce failures caused by a surge voltage when the MOSFET 21 and the IGBT 22 perform operations in parallel, and can suppress a decrease in reliability.

The semiconductor device A1 includes the SBD 23. The SBD 23 is connected in reverse parallel to the MOSFET 21 and the IGBT 22. According to this configuration of the switching circuit 2, even if a switching surge is generated by the switching operation of the switching circuit 2, a switching surge applied to the MOSFET 21 and the IGBT 22 is reduced by the energization of the SBD 23, thereby avoiding failures of the MOSFET 21 and the IGBT 22, as with the case of the switching circuit 1. In other words, even if a switching surge is generated during the switching operations of the MOSFET 21 and the IGBT 22, the semiconductor device A1 can reduce failures caused by the switching surge and suppress a decrease in reliability. In particular, according to the semiconductor device A1, a sixth conduction path from the power terminal 41 to the SBD 23 is longer than the fourth conduction path from the power terminal 41 to the MOSFET 21, and is shorter than the fifth conduction path from the power terminal 41 to the IGBT 22. Such a configuration is effective in reducing a switching surge applied to the MOSFET 21 and the IGBT 22. For example, in the semiconductor device A1, when the power terminal 41 is arranged on one side of the switching circuit 1, the SBD 23 is arranged between the MOSFET 21 and the IGBT 22 in the second arrangement direction. This results in the sixth conduction path being longer than the fourth conduction path and shorter than the fifth conduction path.

In the semiconductor device A1, the power terminal 41 and the power terminal 42 are located opposite from the IGBT 12 with respect to the MOSFET 11 in the arrangement direction (first arrangement direction) of the MOSFET 11 and the IGBT 12. Furthermore, the power terminal 41 and the power terminal 42 are located opposite from the IGBT 22 with respect to the MOSFET 21 in the arrangement direction (second arrangement direction) of the MOSFET 21 and the IGBT 22. According to this configuration, in the conduction paths of the main current between the power terminal 41 and the power terminal 42, the conduction paths passing through the two MOSFETs 11 and 21 are shorter than the conduction paths passing through the two IGBTs 12 and 22. In a low current range (e.g., approximately 100 A), the current in the semiconductor device A1 preferentially flows through the relatively shorter conduction paths that pass through the two MOSFETs 11 and 21. In general, a MOSFET has a smaller on-resistance than an IGBT in a low current range. Since the current in the semiconductor device A1 preferentially flows through the MOSFETs 11 and 21 rather than the IGBTs 12 and 22 in the low current range, it is possible to reduce a power loss caused by on-resistance. For example, when used in an in-vehicle inverter, the semiconductor device A1 is often operated under a light load (where the current flowing through the semiconductor device A1 is within a low current range). Therefore, when used in an in-vehicle inverter, the semiconductor device A1 can effectively reduce a power loss caused by the on-resistance of each of the MOSFETs 11, 21 and the IGBTs 12, 22.

In the first embodiment, the inductance of the first conduction path is made smaller than the inductance of the second conduction path by the difference between the length of the first conduction path from the power terminal 41 to the drain 111 of the MOSFET 11 and the length of the second conduction path from the power terminal 41 to the collector 121 of the IGBT 12. Instead of this configuration, the inductance of the first conduction path may be made smaller than the inductance of the second conduction path by employing a different constituent material or a different shape for each of the first conduction path and the second conduction path.

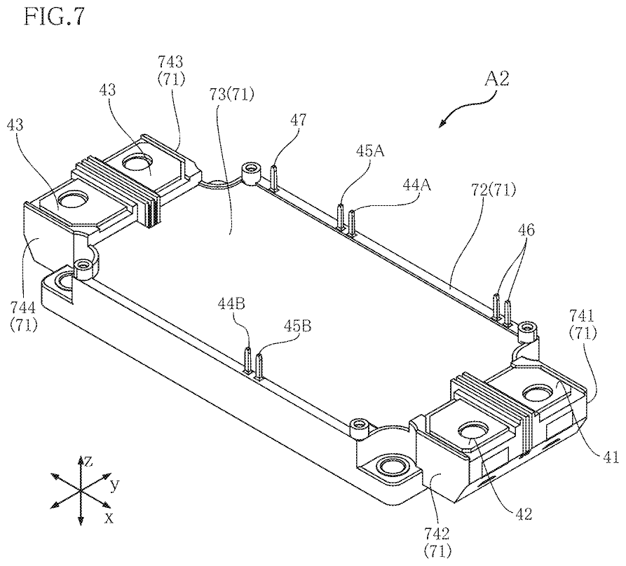

FIGS. 7 to 13 show a semiconductor device A2 according to a second embodiment. As shown in FIGS. 7 to 13, the semiconductor device A2 includes two switching circuits 1 and 2, a supporting member 3, a plurality of outer terminals, a plurality of connecting members, a heat dissipating plate 70, a case 71, and a resin member 75. The outer terminals include a plurality of power terminals 41 to 43, and a plurality of signal terminals 44A, 44B, 45A, 45B, 46, and 47. The connecting members include a plurality of power connecting members 511 to 513, and 521 to 523, and a plurality of signal connecting members 541A, 541B, 542A, 542B, 551A, 551B, 552A, 552B, 540A, 540B, 550A, 550B, 56, and 57.

The semiconductor device A2 has a different module structure from the semiconductor device A1. For example, the semiconductor device A2 is different from the semiconductor device A1 in including the heat dissipating plate 70, the case 71, and the resin member 75, instead of the sealing member 6. The heat dissipating plate 70, the case 71, and the resin member 75 protect the two switching circuits 1 and 2, and so on.

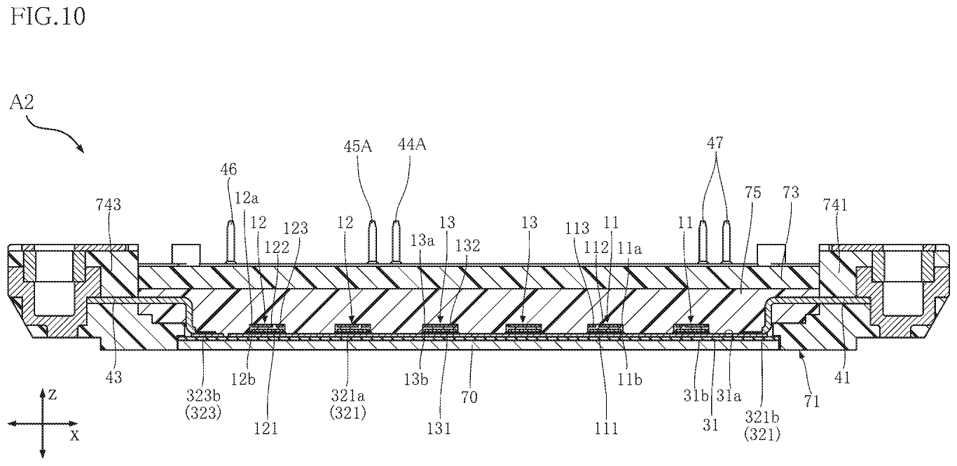

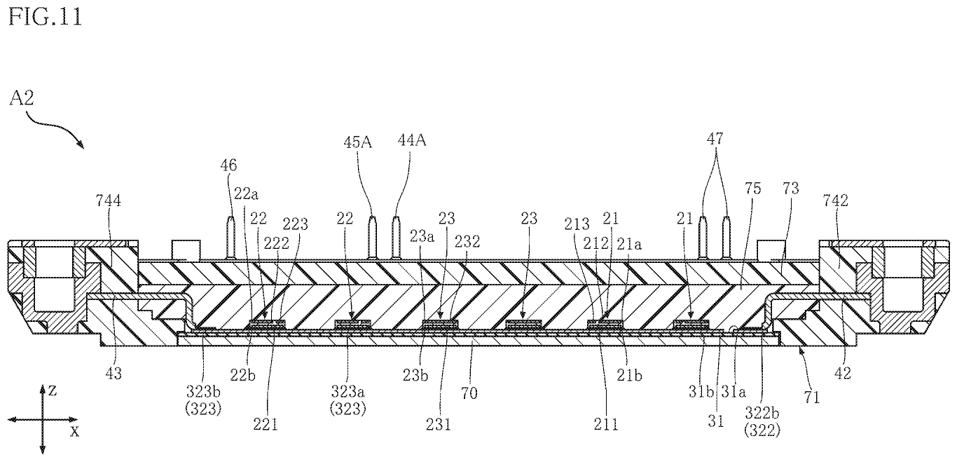

The heat dissipating plate 70 is a flat plate having a rectangular shape in plan view, for example. The heat dissipating plate 70 is made of a highly heat-conductive material such as copper or a copper alloy. The surface of the heat dissipating plate 70 may be plated with Ni. A cooling member (such as a heat sink) may be attached to the lower surface of the heat dissipating plate 70 in the third direction z as necessary. As shown in FIGS. 10 and 11, an insulating substrate 31 is provided on the heat dissipating plate 70.

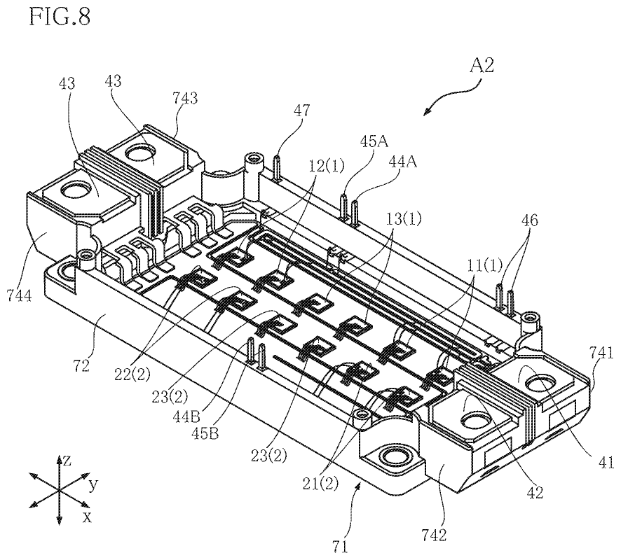

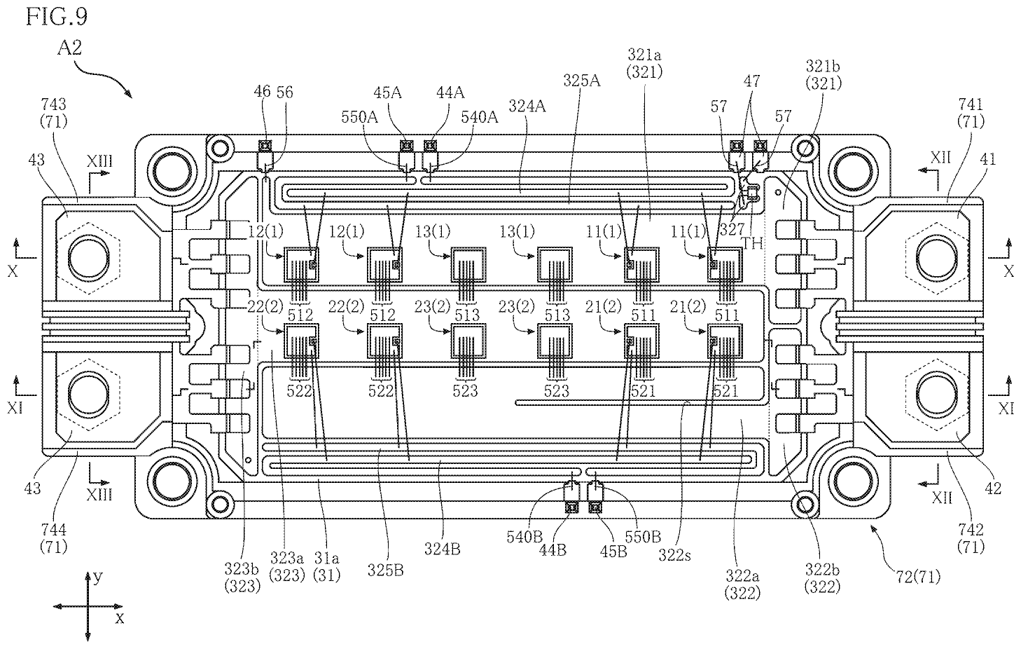

As can be understood from FIGS. 8 and 9, the case 71 has a rectangular parallelepiped shape, for example. The case 71 is made of a synthetic resin that is electrically insulative and has excellent thermal resistance, such as polyphenylene sulfide (PPS). The case 71 has a rectangular shape having substantially the same size as the heat dissipating plate 70 in plan view. As shown in FIGS. 7 to 13, the case 71 includes a frame 72, a top plate 73, a plurality of terminal blocks 741 to 744.

The frame 72 is fixed to the upper surface of the heat dissipating plate 70 in the third direction z. The top plate 73 is fixed to the frame 72. As shown in FIGS. 7, 10, and 11, the top plate 73 closes an opening of the frame 72 located upward in the third direction z. As shown in FIGS. 10 and 11, the top plate 73 faces the heat dissipating plate 70 that closes the frame 72 at the lower side in the third direction z. The top plate 73, the heat dissipating plate 70, and the frame 72 define a circuit housing space (i.e., a space that houses the switching circuits 1 and 2, etc.) within the case 71.

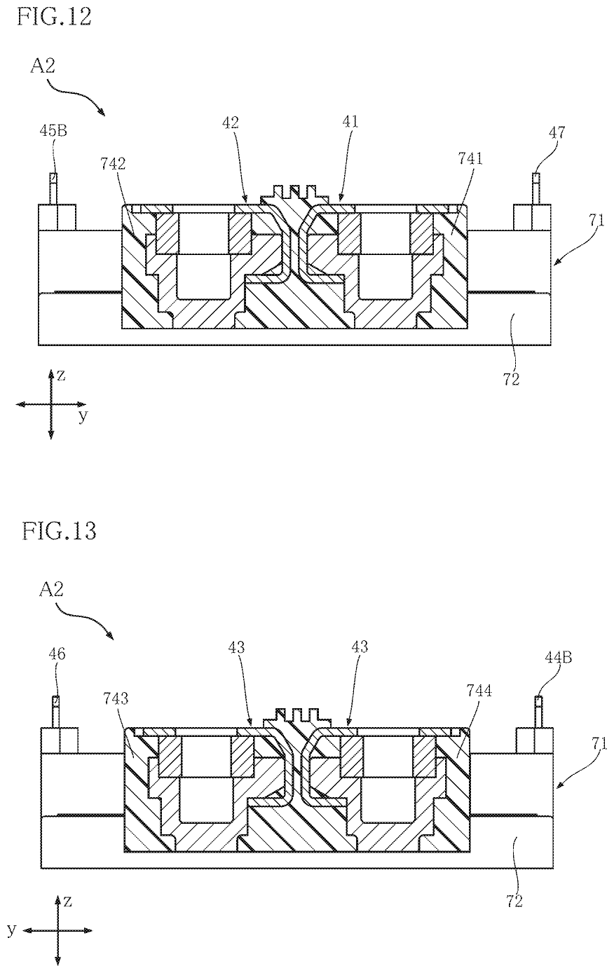

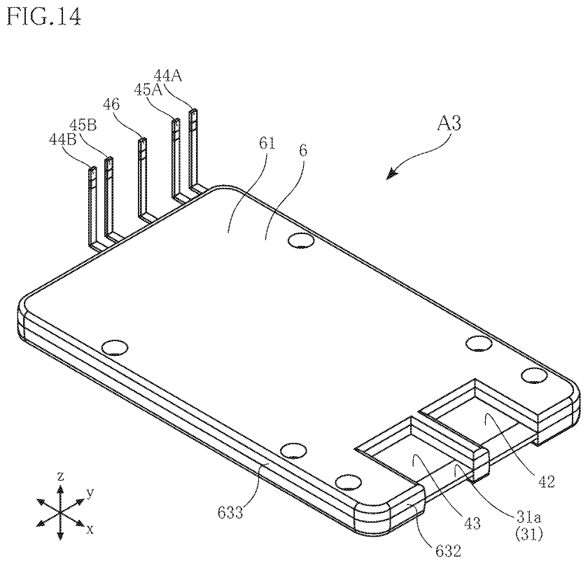

The two terminal blocks 741 and 742 are offset from the frame 72 in a sense of the first direction x, and are integrally formed with the frame 72. The two terminal blocks 743 and 744 are offset from the frame 72 in the other sense of the first direction x, and are integrally formed with the frame 72. The two terminal blocks 741 and 742 are arranged in the second direction y and against the side wall of the frame 72 in one sense of the first direction x. As shown in FIGS. 10 and 12, the terminal block 741 partially covers the power terminal 41, and a portion of the power terminal 41 is arranged on the upper surface of the terminal block 741 in the third direction z. As shown in FIGS. 11 and 12, the terminal block 742 partially covers the power terminal 42, and a portion of the power terminal 42 is arranged on the upper surface of the terminal block 742 in the third direction z. The two terminal blocks 743 and 744 are arranged in the second direction y and against the side wall of the frame 72 in the other sense of the first direction x. As shown in FIGS. 10 and 13, the terminal block 743 partially covers one of the two power terminals 43, and a portion of the power terminal 43 is arranged on the upper surface of the terminal block 743 in the third direction z. As shown in FIGS. 11 and 13, the terminal block 744 partially covers the other one of the two power terminals 43, and a portion of the power terminal 43 is arranged on the upper surface of the terminal block 744 in the third direction z.

As shown in FIGS. 10 and 11, the resin member 75 fills the area surrounded by the heat dissipating plate 70 and the case 71. The resin member 75 covers the two switching circuits 1 and 2, and so on. The constituent material of the resin member 75 is a black epoxy resin, for example. The constituent material of the resin member 75 may be other than epoxy resin, such as silicone gel. The semiconductor device A2 may not include the resin member 75. In an example where the semiconductor device A2 includes the resin member 75, the case 71 may not include the top plate 73.

The switching circuit 1 of the semiconductor device A2 includes two MOSFETs 11, two IGBTs 12, and two SBDs 13. They are arranged in order of the two MOSFETs 11, the two SBDs 13, and the two IGBTs 12, from the two power terminals 41 and 42 to the two power terminals 43 in the first arrangement direction (the same direction as the first direction x in the semiconductor device A2). Accordingly, the two MOSFETs 11 are closer to the two power terminals 41 and 42 than the two IGBTs 12, and the two SBDs 13 are arranged between each of the two MOSFETs 11 and each of the two IGBTs 12.

The switching circuit 2 of the semiconductor device A2 includes two MOSFETs 21, two IGBTs 22, and two SBDs 23. They are arranged in order of the two MOSFETs 21, the two SBDs 23, and the two IGBTs 22, from the two power terminals 41 and 42 to the two power terminals 43 in the second arrangement direction (the same direction as the first direction x in the semiconductor device A2). Accordingly, the two MOSFETs 21 are closer to the two power terminals 41 and 42 than the two IGBTs 22, and the two SBDs 23 are arranged between each of the two MOSFETs 21 and each of the two IGBTs 22.

The supporting member 3 has an insulating substrate 31 and an obverse-surface metal layer 32. The supporting member 3 of the semiconductor device A2 is different from the supporting member 3 of the semiconductor device A1 in not including the reverse-surface metal layer 33. In the semiconductor device A2, a reverse surface 31b of the insulating substrate 31 is bonded to the heat dissipating plate 70. Unlike this configuration, the supporting member 3 of the semiconductor device A2 may also include a reverse-surface metal layer 33 as with the supporting member 3 of the semiconductor device A1.

The obverse-surface metal layer 32 of the semiconductor device A2 includes a plurality of power wiring sections 321 to 323, and a plurality of signal wiring sections 324A, 324B, 325A, 325B, 327, and 329. Accordingly, the obverse-surface metal layer 32 of the semiconductor device A2 is different from the obverse-surface metal layer 32 of the semiconductor device A1 in further including a pair of signal wiring sections 327.

As shown in FIG. 9, the pair of signal wiring sections 327 are spaced apart from each other in the second direction y. The pair of signal wiring sections 327 are bonded to a thermistor TH, for example. The thermistor TH is provided across the pair of signal wiring sections 327. In a configuration different from that of the semiconductor device A2, the thermistor TH may not be bonded to the pair of signal wiring sections 327. As shown in FIG. 9, the pair of signal wiring sections 327 are located near one of the four corners of the insulating substrate 31. As shown in FIG. 9, the pair of signal wiring sections 327 are located between a pad portion 321b and the two signal wiring sections 324A and 325A in the first direction x.

In the semiconductor device A2, a slit 322s is formed in a pad portion 322a of the power wiring section 322, as shown in FIG. 9. The slit 322s extends in the first direction x from a base end which is the edge of the pad portion 322a in one sense of the first direction x (where a pad portion 322b is located) in plan view. A tip of the slit 322s is positioned at the center of the pad portion 322a in the first direction x.

In the semiconductor device A2, the outer terminals include the power terminals 41 to 43 and the signal terminals 44A, 44B, 45A, 45B, 46, and 47, as described above. Accordingly, the outer terminals of the semiconductor device A2 are different from the outer terminals of the semiconductor device A1 in further including the signal terminals 46 and 47 and do not include the signal terminals 49. In the semiconductor device A2, the power terminals 41 to 43 are respectively supported by the terminal blocks 741 to 744, and the signal terminals 44A, 44B, 45A, 45B, 46, and 47 are supported by the case 71.

As shown in FIG. 9, the signal connecting member 56 is bonded to the signal terminal 46. The signal terminal 46 is electrically connected to the power wiring section 321 via the signal connecting member 56. As a result, the signal terminal 46 is electrically connected to drains 111 of the MOSFETs 11 and collectors 121 of the IGBTs 12. The signal terminal 46 is an output terminal for a third detection signal. The third detection signal is a signal for detecting the voltage applied to the power wiring section 321.

As shown in FIG. 9, the pair of signal connecting members 57 are bonded to the pair of signal terminals 47, respectively. The pair of signal terminals 47 are electrically connected to the pair of signal wiring sections 327 via the pair of signal connecting members 57. As a result, the pair of signal terminals 47 are electrically connected to the thermistor TH. The pair of signal terminals 47 are terminals for detecting a temperature within the case 71. When the thermistor TH is not bonded to the pair of signal wiring sections 327, the pair of signal terminals 47 will be non-connected terminals.

In the semiconductor device A2, the connecting members include the power connecting members 511 to 513, and 521 to 523, and the signal connecting members 541A, 541B, 542A, 542B, 551A, 551B, 552A, 552B, 540A, 540B, 550A, 550B, 56, and 57, as described above. Accordingly, the connecting members of the semiconductor device A2 are different from the connecting members of the semiconductor device A1 in further including the signal connecting members 540A, 540B, 550A, 550B, 56, and 57. In the example shown in FIG. 9, each of the power connecting members 511 to 513, and 521 to 523 of the semiconductor device A2 is a bonding wire, but may be a metallic flat plate instead, as with the case of the semiconductor device A1.

Each of the signal connecting members 540A, 540B, 550A, 550B, 56, and 57 may be a bonding wire, for example. The constituent material of each of the signal connecting members 540A, 540B, 550A, 550B, 56, and 57 is gold or a gold alloy, for example. The constituent material may be copper, a copper alloy, aluminum, or an aluminum alloy instead of gold or a gold alloy.

The signal connecting member 540A is bonded to the signal wiring section 324A and the signal terminal 44A in the circuit housing space of the case 71. The signal connecting member 540A electrically connects the signal wiring section 324A and the signal terminal 44A.

The signal connecting member 540B is bonded to the signal wiring section 324B and the signal terminal 44B in the circuit housing space of the case 71. The signal connecting member 540B electrically connects the signal wiring section 324B and the signal terminal 44B.

The signal connecting member 550A is bonded to the signal wiring section 325A and the signal terminal 45A in the circuit housing space of the case 71. The signal connecting member 550A electrically connects the signal wiring section 325A and the signal terminal 45A.

The signal connecting member 550B is bonded to the signal wiring section 325B and the signal terminal 45B in the circuit housing space of the case 71. The signal connecting member 550B electrically connects the signal wiring section 325B and the signal terminal 45B.

The signal connecting member 56 is bonded to a pad portion 321a and the signal terminal 46 in the circuit housing space of the case 71. The signal connecting member 56 electrically connects the power wiring section 321 and the signal terminal 46.

The pair of signal connecting members 57 are respectively bonded to the pair of signal wiring sections 327 and the pair of signal terminals 47 in the circuit housing space of the case 71. Each of the pair of signal connecting members 57 electrically connects one of the pair of signal wiring sections 327 and one of the pair of signal terminals 47.

The semiconductor device A2 is similar to the semiconductor device A1 in that the element withstand voltage of each of the MOSFETs 11 is larger than the element withstand voltage of each of the IGBTs 12. Accordingly, as with the semiconductor device A1, the semiconductor device A2 can reduce failures caused by a surge voltage when the MOSFETs 11 and the IGBTs 12 perform operations in parallel, and can suppress a decrease in reliability. In the semiconductor device A2, the element withstand voltage of each of the MOSFETs 21 is larger than the element withstand voltage of each of the IGBTs 22. Accordingly, as with the semiconductor device A1, the semiconductor device A2 can reduce failures caused by a surge voltage when the MOSFETs 21 and the IGBTs 22 perform operations in parallel, and can suppress a decrease in reliability. Furthermore, the semiconductor device A2 has advantages similar to the semiconductor device A1 owing to its common configuration with the semiconductor device A1.

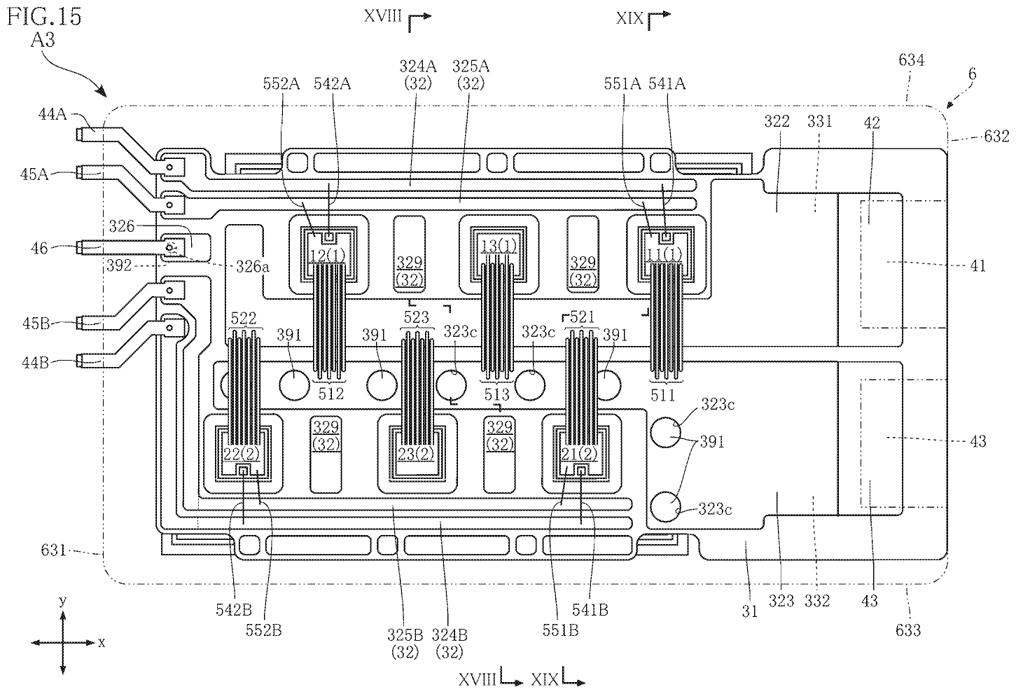

FIGS. 14 to 19 show a semiconductor device A3 according to a third embodiment. As shown in FIGS. 14 to 19, the semiconductor device A3 includes two switching circuits 1 and 2, a supporting member 3, a plurality of outer terminals, a plurality of connecting members, and a sealing member 6. The outer terminals include a plurality of power terminals 41 to 43, and a plurality of signal terminals 44A, 44B, 45A, 45B, and 46. The connecting members include a plurality of power connecting members 511 to 513, and 521 to 523, and a plurality of signal connecting members 541A, 541B, 542A, 542B, 551A, 551B, 552A, and 552B.

The semiconductor device A3 has a different module structure from each of the semiconductor devices A1 and A2. For example, the semiconductor device A3 is similar to the semiconductor device A1 in that the semiconductor device A3 is of a resin mold type where the two switching circuits 1 and 2 are covered with the sealing member 6, but is different from the semiconductor device A1 in the configurations of the supporting member 3, the outer terminals, and the connecting members.

The supporting member 3 of the semiconductor device A3 includes an insulating substrate 31, an obverse-surface metal layer 32, a reverse-surface metal layer 33, a pair of conductive plates 34A and 34B, a pair of insulating plates 35A and 35B, and a plurality of metal members 391 and 392.

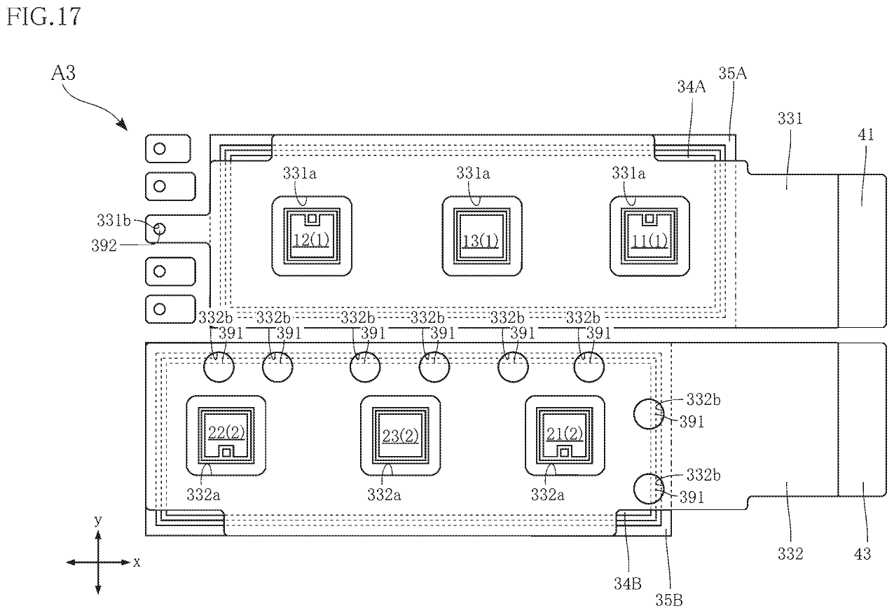

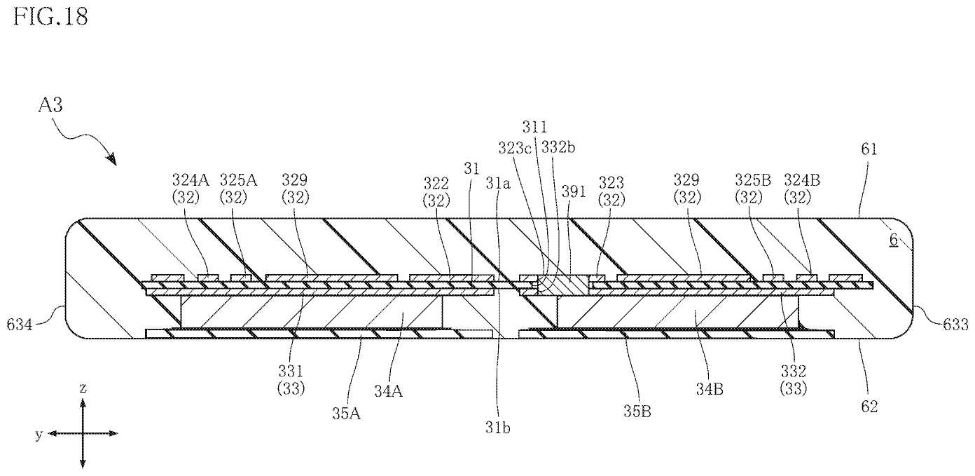

Each of the pair of conductive plates 34A and 34B is made of a conductive material, which is copper or a copper alloy, for example. Unlike this configuration, each of the conductive plates 34A and 34B may be a laminate formed by alternately stacking a copper layer and a molybdenum layer in the third direction z. In this case, the surface layer of each of the pair of conductive plates 34A and 34B in the third direction z is a copper layer. Each of the pair of conductive plates 34A and 34B is arranged such that the thickness direction thereof coincides (or substantially coincides) with the third direction z. As shown in FIG. 17, each of the pair of conductive plates 34A and 34B has a rectangular shape in plan view, for example.

As shown in FIG. 17, for example, a MOSFET 11, an IGBT 12, and an SBD 13 are mounted on the conductive plate 34A. The conductive plate 34A is electrically connected to a drain 111 of the MOSFET 11, a collector 121 of the IGBT 12, and a cathode 132 of the SBD 13. The drain 111, the collector 121, and the cathode 132 are electrically connected to each other via the conductive plate 34A. The conductive plate 34A has a rectangular parallelepiped shape, for example.

As shown in FIG. 17, a MOSFET 21, an IGBT 22, and an SBD 23 are mounted on the conductive plate 34B. The conductive plate 34B is electrically connected to a drain 211 of the MOSFET 21, a collector 221 of the IGBT 22, and a cathode 232 of the SBD 23. The drain 211, the collector 221, and the cathode 232 are electrically connected to each other via the conductive plate 34B. The conductive plate 34B has a rectangular parallelepiped shape, for example.

Each of the pair of insulating plates 35A and 35B is made of a ceramic such as AlN, SiN, or Al₂O₃, for example. As shown in FIG. 17, each of the pair of insulating plates 35A and 35B has a rectangular shape in plan view, for example.

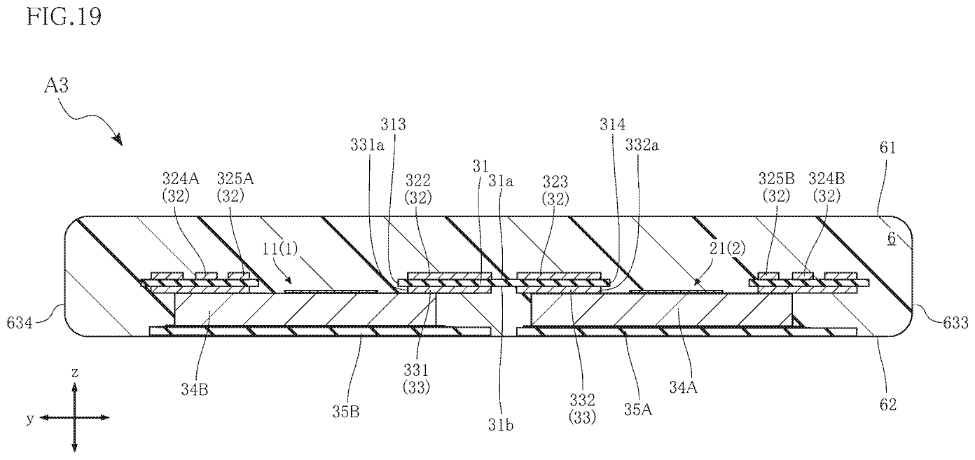

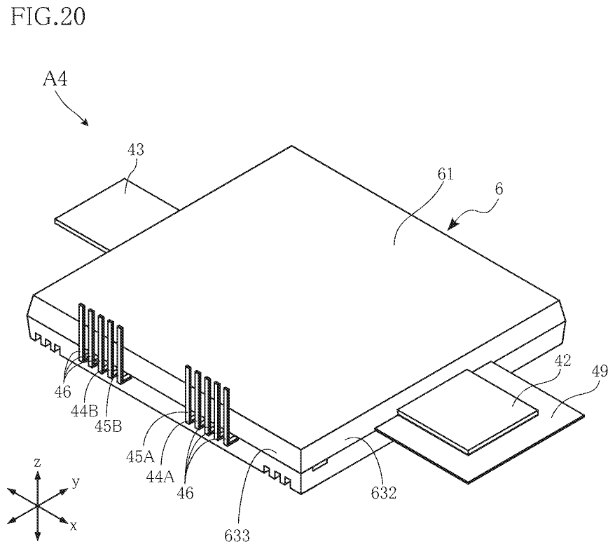

As shown in FIGS. 18 and 19, the insulating plate 35A is bonded to the conductive plate 34A, and supports the conductive plate 34A. A plating layer may be formed on the surface of the insulating plate 35A to which the conductive plate 34A is bonded. The plating layer may be made of silver or a silver alloy, for example. In the example shown in FIGS. 18 and 19, the surface of the insulating plate 35A that faces downward in the third direction z is exposed from the sealing member 6. Unlike this configuration, the surface of the insulating plate 35A that faces downward in the third direction z may be covered with the sealing member 6.

As shown in FIGS. 18 and 19, the insulating plate 35B is bonded to the conductive plate 34B, and supports the conductive plate 34B. A plating layer may be formed on the surface of the insulating plate 35B to which the conductive plate 34B is bonded. The plating layer may be made of silver or a silver alloy, for example. In the example shown in FIGS. 18 and 19, the surface of the insulating plate 35B that faces downward in the third direction z is exposed from the sealing member 6. Unlike this configuration, the surface of the insulating plate 35B that faces downward in the third direction z may be covered with the sealing member 6.

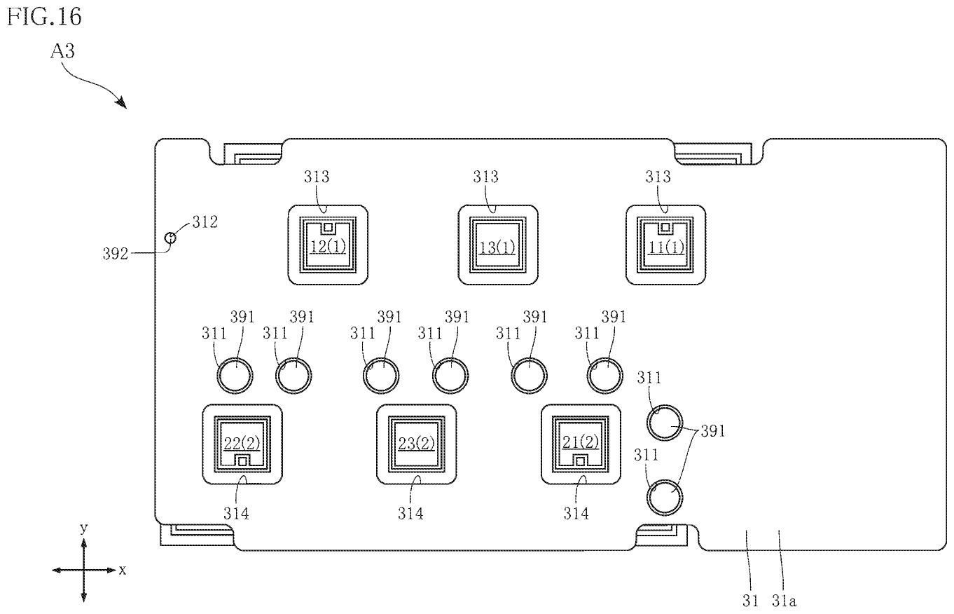

As shown in FIG. 16, the insulating substrate 31 of the semiconductor device A3 includes a plurality of through holes 311, a through hole 312, a plurality of openings 313, and a plurality of openings 314.

As shown in FIG. 18, each of the through holes 311 penetrates through the insulating substrate 31 from an obverse surface 31a to a reverse surface 31b in the thickness direction (third direction z) of the insulating substrate 31. As shown in FIGS. 16 and 18, the metal members 391 are inserted into the respective through holes 311. As shown in FIGS. 16 and 18, the inner surface of each of the through holes 311 is not in contact with a metal member 391. Unlike the configuration, the inner surface of each of the through holes 311 may be in contact with a metal member 391. In the present disclosure, “inserted” refers to a state where a member (e.g., a metal member 391) is inserted into a through hole (e.g., a through hole 311), regardless of whether the member is in contact with the inner surface of the through hole. An insulating member different from the insulating substrate 31 may be formed in a clearance between each of the metal members 391 and each of the through holes 311.

The through hole 312 penetrates through the insulating substrate 31 from the obverse surface 31a to the reverse surface 31b in the thickness direction (third direction z) of the insulating substrate 31. As shown in FIG. 16, the metal member 392 is inserted into the through hole 312. Although the inner surface of the through hole 312 is in contact with the metal member 392 (see FIG. 16) in the illustrated example, the metal member 392 may not be in contact with the metal member 392 in another example.

As shown in FIG. 19, each of the openings 313 penetrates through the insulating substrate 31 from the obverse surface 31a to the reverse surface 31b in the thickness direction (third direction z) of the insulating substrate 31. As shown in FIG. 16, each of the openings 313 surrounds one of the MOSFET 11, the IGBT 12, and the SBD 13 in plan view.

As shown in FIG. 19, each of the openings 314 penetrates through the insulating substrate 31 from the obverse surface 31a to the reverse surface 31b in the thickness direction (third direction z) of the insulating substrate 31. As shown in FIG. 16, each of the openings 314 surrounds one of the MOSFET 21, the IGBT 22, and the SBD 23 in plan view.

In the semiconductor device A3, the obverse-surface metal layer 32 includes two power wiring sections 322 and 323, and a plurality of signal wiring sections 324A, 324B, 325A, 325B, 326, and 329, and the reverse-surface metal layer 33 includes two power wiring sections 331 and 332.

In the semiconductor device A3, the power wiring sections 322, 323, 331, and 332 form conductive paths for the main current. The power wiring section 322 and the power wiring section 331 overlap with each other in plan view, and the power wiring section 323 and the power wiring section 332 overlap with each other in plan view.

The power wiring section 331 is formed on the reverse surface 31b of the insulating substrate 31. As shown in FIGS. 18 and 19, the power wiring section 331 is bonded to the conductive plate 34A. The power wiring section 331 is electrically connected to the drain 111 of the MOSFET 11, the collector 121 of the IGBT 12, and the cathode 132 of the SBD 13 via the conductive plate 34A.

As shown in FIGS. 17 and 19, the power wiring section 331 includes a plurality of openings 331a and a through hole 331b. As shown in FIG. 19, the openings 331a penetrate the power wiring section 331 in the third direction z (i.e., the thickness direction of the power wiring section 331). As can be understood from FIG. 19, the openings 331a overlap with the respective openings 313 of the insulating substrate 31 in plan view. As shown in FIG. 17, each of the openings 331a surrounds one of the MOSFET 11, the IGBT 12, and the SBD 13 in plan view. The through hole 331b penetrates through the power wiring section 331 in the third direction z (i.e., the thickness direction of the power wiring section 331). As shown in FIG. 17, the metal member 392 is fitted in the through hole 331b, and the inner surface of the through hole 331b is in contact with the metal member 392. In the present disclosure, “fitted” refers to a state where a member (e.g., the metal member 392) is placed inside a through hole (e.g., the through hole 311b) and in contact with the inner surface of the through hole. In other words, the “fitted” state corresponds to one of the “inserted” states of a member where the member is in contact with the inner surface of a through hole.

The power wiring section 332 is formed on the reverse surface 31b of the insulating substrate 31. As shown in FIGS. 18 and 19, the power wiring section 332 is bonded to the conductive plate 34B. The power wiring section 332 is electrically connected to the drain 211 of the MOSFET 21, the collector 221 of the IGBT 22, and the cathode 232 of the SBD 23. Owing to the configuration described below, the power wiring section 332 is also electrically connected to a source 112 of the MOSFET 11, an emitter 122 of the IGBT 12, and an anode 131 of the SBD 13 via the metal members 391.

As shown in FIGS. 17 to 19, the power wiring section 332 includes a plurality of openings 332a and a plurality of through holes 332b. As shown in FIGS. 17 and 19, the openings 332a penetrate the power wiring section 332 in the third direction z (i.e., the thickness direction of the power wiring section 332). As can be understood from FIG. 19, the openings 332a overlap with the respective openings 314 of the insulating substrate 31 in plan view. As shown in FIG. 17, each of the openings 332a surrounds one of the MOSFET 22, the IGBT 22, and the SBD 23 in plan view. As shown in FIG. 18, the through holes 332b penetrate through the power wiring section 332 in the third direction z (i.e., the thickness direction of the power wiring section 332). As can be understood from FIG. 18, each of the through holes 332b overlaps with one of a plurality of through holes 323c of the power wiring section 323 in plan view. A metal member 391 is fitted in each of the through holes 332b, and the inner surface of the through hole 332b is in contact with the metal member 391. In the illustrated example, each of the through holes 332b has a circular shape in plan view (see FIG. 17), but the shape may be changed appropriately according to the shape of each of the metal members 391.

The power wiring section 322 is formed on the obverse surface 31a of the insulating substrate 31. As shown in FIG. 15, the power connecting members 521 to 523 are bonded to the power wiring section 322, and the power wiring section 322 is electrically connected to a source 212 of the MOSFET 21, an emitter 222 of the IGBT 22, and an anode 231 of the SBD 23 via the power connecting members 521 to 523.

The power wiring section 323 is formed on the obverse surface 31a of the insulating substrate 31. As shown in FIG. 15, the power connecting members 511 to 513 are bonded to the power wiring section 323, and the power wiring section 323 is electrically connected to the source 112 of the MOSFET 11, the emitter 122 of the IGBT 12, and the anode 131 of the SBD 13 via the power connecting members 511 to 513. Owing to the configuration described below, the power wiring section 323 is also electrically connected to the drain 211 of the MOSFET 21, the collector 221 of the IGBT 22, and the cathode 232 of the SBD 23 via the metal members 391.

As shown in FIG. 15, the power wiring section 323 includes the through holes 323c. As shown in FIG. 18, the through holes 323c penetrate the power wiring section 323 in the third direction z (i.e., the thickness direction of the power wiring section 323). As shown in FIGS. 15 and 18, a metal member 391 is fitted in each of the through holes 323c, and the inner surface of the through hole 323c is in contact with the metal member 391. In the illustrated example, each of the through holes 323c has a circular shape in plan view (see FIG. 15), but the shape may be changed appropriately according to the shape of each of the metal members 391.

As shown in FIG. 18, the metal members 391 penetrate through the insulating substrate 31 in the third direction z (i.e., the thickness direction of the insulating substrate 31), and electrically connect the power wiring section 323 and the power wiring section 332. Accordingly, the power wiring section 323 has the same electrical potential as the power wiring section 332 via the metal members 391. In other words, the power wiring section 323 and the power wiring section 332 are electrically connected to the source 112 of the MOSFET 11, the emitter 122 of the IGBT 12, and the anode 131 of the SBD 13, and are also electrically connected to the drain 211 of the MOSFET 21, the collector 221 of the IGBT 22, and the cathode 232 of the SBD 23. Each of the metal members 391 has a columnar shape, for example. In the illustrated example, each of the metal members 391 has a circular shape (see FIGS. 15 to 17) in plan view, but may have an elliptical or polygonal shape in plan view instead of a circular shape. The constituent material of each of the metal members 391 is copper or a copper alloy, for example.

As shown in FIGS. 15 to 18, the metal members 391 are fitted in the through holes 323c of the power wiring section 323 and the through holes 332b of the power wiring section 332, and are inserted into the through holes 311 of the insulating substrate 31. Each of the metal members 391 is in contact with the inner surface of a through hole 323c and the inner surface of a through hole 332b. Each of the metal members 391 is fitted in and supported by a through hole 323c and a through hole 332b. When there is a clearance between each of the metal members 391 and each of the through holes 323c and between each of the metal members 391 and the inner surface of each of the through holes 332b, solder may be injected into the clearance. The injected solder fills the clearance and fixes the metal member 391 to the power wiring section 323 and the power wiring section 332. Note that the injected solder may also fill a clearance between each of the metal members 391 and the inner surface of each of the through holes 311 of the insulating substrate 31.

The metal member 392 penetrates the insulating substrate 31 in the third direction z (i.e., the thickness direction of the insulating substrate 31), and electrically connects the power wiring section 331 and the signal wiring section 326. The metal member 392 has a columnar shape, for example. In the illustrated example, the metal member 392 has a circular shape (see FIGS. 15 to 17) in plan view, but may have an elliptical or polygonal shape in plan view instead of a circular shape. The constituent material of the metal member 392 is copper or a copper alloy, for example.

As shown in FIGS. 15 to 17, the metal member 392 is fitted in a through hole 326a of the signal wiring section 326 and the through hole 331b of the power wiring section 331, and is inserted into the through hole 312 of the insulating substrate 31. As shown in FIGS. 15 to 17, the metal member 392 is in contact with the inner surface of the through hole 326a, the inner surface of the through hole 331b, and the inner surface of the through hole 312. When there is a clearance between the metal member 392 and the inner surface of each of the through holes 326a, 331b, and 312, solder may be injected into the clearance. The injected solder fills the clearance and fixes the metal member 392 to the power wiring section 322, the signal wiring section 326, and the insulating substrate 31.

As can be understood from FIGS. 15 and 19, each of the MOSFET 11, the IGBT 12, and the SBD 13 in the semiconductor device A3 is accommodated in a recess defined by an opening 313 of the insulating substrate 31, an opening 331a of the power wiring section 331, and the conductive plate 34A. In the illustrated example, an obverse surface 11a of the MOSFET 11, an obverse surface 12a of the IGBT 12, and an obverse surface 13a of the SBD 13 each overlap with either the insulating substrate 31 or the power wiring section 331 as viewed in a direction (e.g., second direction y) perpendicular to the third direction z, but may overlap with the power wiring section 322 in another example. In either example, the MOSFET 11, the IGBT 12, and the SBD 13 do not protrude upward in the third direction z from the power wiring section 322. Similarly, as can be understood from FIGS. 15 and 19, each of the MOSFET 21, the IGBT 22, and the SBD 23 is accommodated in a recess defined by an opening 314 of the insulating substrate 31, an opening 332a of the power wiring section 332, and the conductive plate 34B. In the illustrated example, an obverse surface 21a of the MOSFET 21, an obverse surface 22a of the IGBT 22, and an obverse surface 23a of the SBD 23 each overlap with either the insulating substrate 31 or the power wiring section 332 as viewed in a direction (e.g., second direction y) perpendicular to the third direction z, but may overlap with the power wiring section 323 in another example. In either example, the MOSFET 21, the IGBT 22, and the SBD 23 do not protrude upward in the third direction z from the power wiring section 323.

In the semiconductor device A3, the power terminal 41 is not a metal plate, but is a part of the power wiring section 331. The power terminal 42 is not a metal plate, but is a part of the power wiring section 332. One of the two power terminals 43 is not a metal plate, but is a part of the power wiring section 323. The other one of the two power terminals 43 is not a metal plate, but is a part of the power wiring section 332. The power terminals 41 to 43 are exposed from the sealing member 6. The surface of each of the power terminals 41 to 43 may or may not be plated. The power terminal 41 and the power terminal 42 overlap with each other in plan view. The two power terminals 43 overlap with each other in plan view. In the illustrated example, the semiconductor device A3 includes the two power terminals 43. However, the semiconductor device A3 may include only one of the two power terminals 43 in another example. In the semiconductor device A3, the power terminals 41 to 43 are offset from the two switching circuits 1 and 2 in one sense of the first direction x. In the switching circuit 1, the MOSFET 11 has the shortest conduction path to the power terminal 41. In the switching circuit 2, the MOSFET 21 has the shortest conduction path to the power terminal 41.

The semiconductor device A3 is similar to the semiconductor devices A1 and A2 in that the element withstand voltage of the MOSFET 11 is larger than the element withstand voltage of the IGBT 12. Accordingly, as with the semiconductor devices A1 and A2, the semiconductor device A3 can reduce failures caused by a surge voltage when the MOSFET 11 and the IGBT 12 perform operations in parallel, and can suppress a decrease in reliability. In the semiconductor device A3, the element withstand voltage of the MOSFET 21 is larger than the element withstand voltage of the IGBT 22. Accordingly, as with the semiconductor devices A1 and A2, the semiconductor device A3 can reduce failures caused by a surge voltage when the MOSFET 21 and the IGBT 22 perform operations in parallel, and can suppress a decrease in reliability. Furthermore, the semiconductor device A3 has advantages similar to each of the semiconductor devices A1 and A2 owing to its common configuration with each of the semiconductor devices A1 and A2.

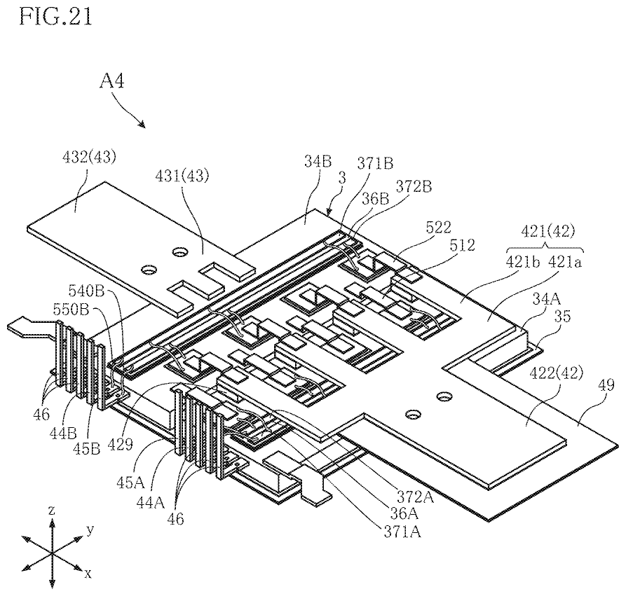

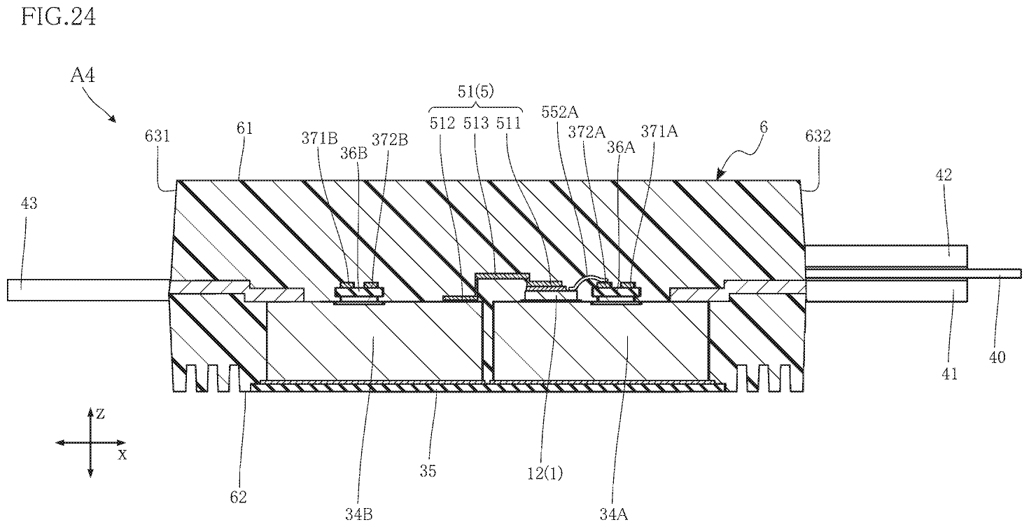

FIGS. 20 to 24 show a semiconductor device A4 according to a fourth embodiment. As shown in FIGS. 20 to 24, the semiconductor device A4 includes two switching circuits 1 and 2, a supporting member 3, a plurality of outer terminals, a plurality of connecting members, and a sealing member 6. The outer terminals include a plurality of power terminals 41 to 43, and a plurality of signal terminals 44A, 44B, 45A, 45B, and 49. The connecting members include a plurality of power connecting members 511 to 513, and 521 to 523, and a plurality of signal connecting members 541A, 541B, 542A, 542B, 551A, 551B, 552A, 552B, 540A, 540B, 550A, and 550B.

The semiconductor device A4 has a different module structure from each of the semiconductor devices A1 to A3. For example, the semiconductor device A4 is similar to each of the semiconductor devices A1 and A3 in that the semiconductor device A4 is of a resin mold type where the two switching circuits 1 and 2 are covered with the sealing member 6, but is different from each of the semiconductor devices A1 and A3 in the configurations of the supporting member 3, the outer terminals, and the connecting members. Description of the semiconductor device A4 is provided with an example where the switching circuit 1 includes one MOSFET 11, two IGBTs 12, and one SBD 13, and the switching circuit 2 includes one MOSFET 21, two IGBTs 22, and one SBD 23.

The supporting member 3 of the semiconductor device A4 includes a pair of conductive plates 34A and 34B, an insulating plate 35, a pair of insulating plates 36A and 36B, and a plurality of signal wiring sections 371A, 371B, 372A, and 372B.

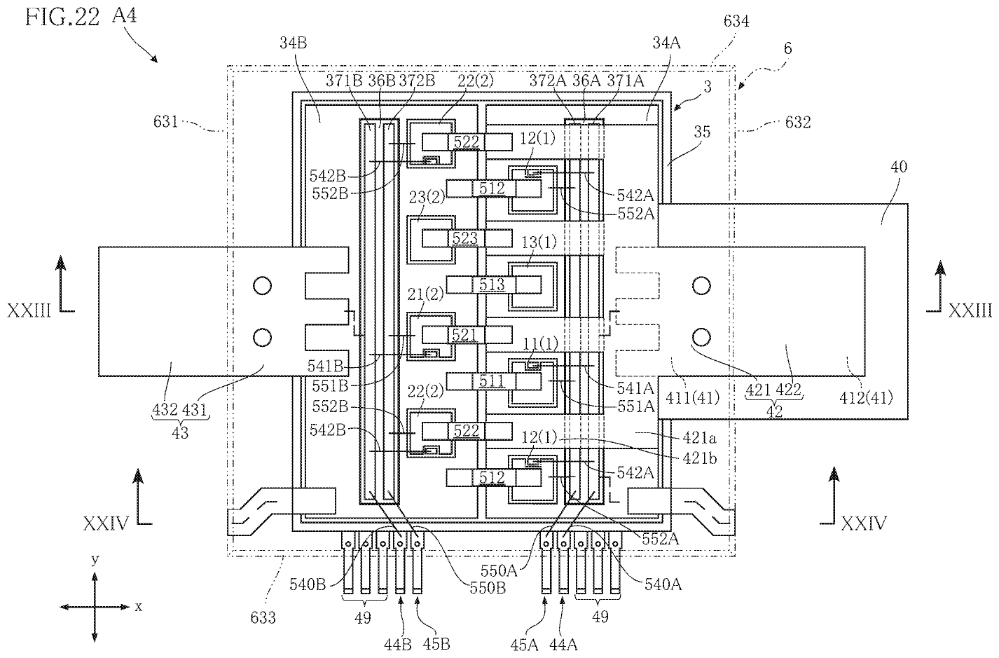

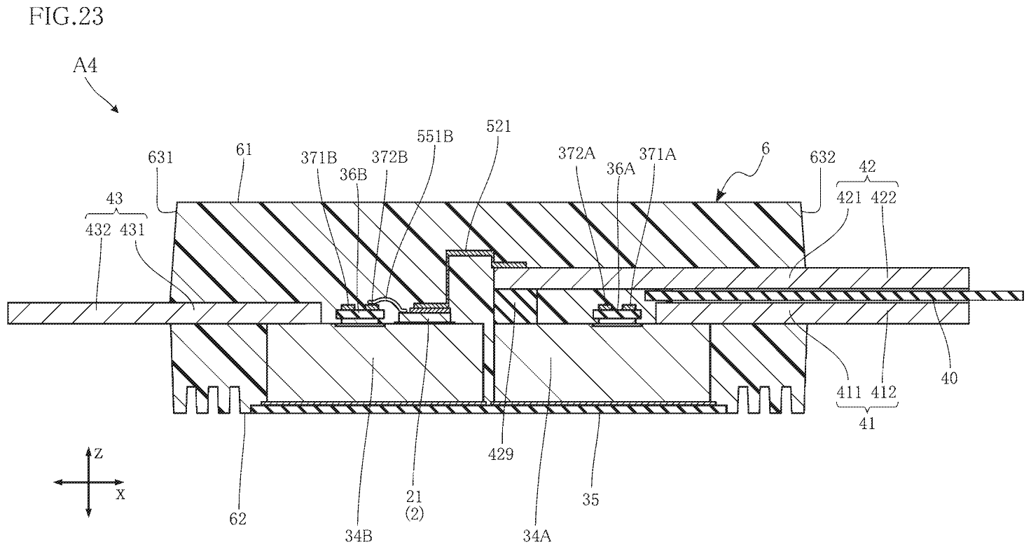

As with the conductive plate 34A of the semiconductor device A3, a conductive plate 34A of the semiconductor device A4 has the switching circuit 1 mounted thereon. However, in the semiconductor device A4, the MOSFET 11, the two IGBTs 12, and the SBD 13 are arranged in the second direction y on the conductive plate 34A, as shown in FIG. 22. The MOSFET 11 and the SBD 13 are arranged between the two IGBTs 12 in the second direction y.

As with the conductive plate 34B of the semiconductor device A3, a conductive plate 34B of the semiconductor device A4 has the switching circuit 2 mounted thereon. However, in the semiconductor device A4, the MOSFET 21, the two IGBTs 22, and the SBD 23 are arranged in the second direction y on the conductive plate 34B, as shown in FIG. 22. The MOSFET 21 and the SBD 23 are arranged between the two IGBTs 22 in the second direction y.

As with the insulating plates 35A and 35B of the semiconductor device A3, the insulating plate 35 is made of a ceramic. The pair of conductive plates 34A and 34B are bonded to the insulating plate 35 so that the insulating plate supports these conductive plates. Unlike this configuration, the semiconductor device A4 may not include the insulating plate 35 but include a pair of insulating plates 35A and 35B as with the semiconductor device A3, and the conductive plate 34A and the conductive plate 34B may be bonded to the insulating plate 35A and the insulating plate respectively.

Each of the pair of insulating plates 36A and 36B is made of glass epoxy resin, for example. As shown in FIGS. 22 to 24, the insulating plate 36A is arranged on the conductive plate 34A. As shown in FIG. 22, the insulating plate 36A has a strip shape extending in the second direction y in plan view. As shown in FIG. 22, the insulating plate 36A is closer to the power terminal 41 than is the switching circuit 1 (the MOSFET 11, the two IGBTs 12, and the SBD 13) in the first direction x. As shown in FIGS. 22 to 24, the insulating plate 36B is arranged on the conductive plate 34B. As shown in FIG. 22, the insulating plate 36B has a strip shape extending in the second direction y in plan view. As shown in FIG. 22, the insulating plate 36B is closer to the power terminal 43 than is the switching circuit 2 (the MOSFET 21, the two IGBTs 22, and the SBD 23) in the first direction x.

As shown in FIGS. 22 to 24, the two signal wiring sections 371A and 372A are arranged on the insulating plate 36A. Each of the two signal wiring sections 371A and 372A is made of copper or a copper alloy, for example. As shown in FIG. 22, each of the two signal wiring sections 371A and 372A has a strip shape extending in the second direction y in plan view. As shown in FIG. 22, the signal connecting members 541A and 542A are bonded to the signal wiring section 371A, so that the signal wiring section 371A is electrically connected to a gate 113 of the MOSFET 11 and a gate 123 of each IGBT 12 via the signal connecting members 541A and 542A. As with the signal wiring section 324A, the signal wiring section 371A transmits a first drive signal. Furthermore, the signal connecting member 540A is bonded to the signal wiring section 371A, so that the signal wiring section 371A is electrically connected to the signal terminal 44A (the input terminal for the first drive signal) via the signal connecting member 540A. The signal connecting members 551A and 552A are bonded to the signal wiring section 372A, so that the signal wiring section 372A is electrically connected to a source 112 of the MOSFET 11 and an emitter 122 of each IGBT 12 via the signal connecting members 551A and 552A. As with the signal wiring section 325A, the signal wiring section 372A transmits a first detection signal. Furthermore, the signal connecting member 550A is bonded to the signal wiring section 372A, so that the signal wiring section 372A is electrically connected to the signal terminal 45A (the output terminal of the first detection signal) via the signal connecting member 550A.

As shown in FIGS. 22 to 24, the two signal wiring sections 371B and 372B are arranged on the insulating plate 36B. Each of the two signal wiring sections 371B and 372B is made of copper or a copper alloy, for example. As shown in FIG. 22, each of the two signal wiring sections 371B and 372B has a strip shape extending in the second direction y in plan view. As shown in FIG. 22, the signal connecting members 541B and 542B are bonded to the signal wiring section 371B, so that the signal wiring section 371B is electrically connected to a gate 213 of the MOSFET 21 and a gate 223 of each IGBT 22 via the signal connecting members 541B and 542B. As with the signal wiring section 324B, the signal wiring section 371B transmits a second drive signal. Furthermore, the signal connecting member 540B is bonded to the signal wiring section 371B, so that the signal wiring section 371B is electrically connected to the signal terminal 44B (the input terminal for the second drive signal) via the signal connecting member 540B. The signal connecting members 551B and 552B are bonded to the signal wiring section 372B, so that the signal wiring section 372B is electrically connected to a source 212 of the MOSFET 21 and an emitter 222 of each IGBT 22 via the signal connecting members 551B and 552B. As with the signal wiring section 325B, the signal wiring section 372B transmits a second detection signal. Furthermore, the signal connecting member 550B is bonded to the signal wiring section 372B, so that the signal wiring section 372B is electrically connected to the signal terminal 45B (the output terminal for the second detection signal) via the signal connecting member 550B.

The power terminal 41 of the semiconductor device A4 has a bonding portion 411 electrically bonded to the conductive plate 34A. In the example shown in FIG. 22, a tip of the bonding portion 411 (the tip being located opposite from the base end that is connected to a terminal portion 412) has a comb-like shape, and this comb-like portion is electrically bonded to the conductive plate 34A. The method for bonding between the bonding portion 411 and the conductive plate 34A is not particularly limited. For example, the bonding may be achieved by any of laser bonding, ultrasonic bonding, or bonding with a conductive bonding member.

The power terminal 42 of the semiconductor device A4 has a bonding portion 421 composed of a connecting part 421a and a plurality of extending parts 421b. The connecting part 421a is connected to a terminal portion 422. The connecting part 421a is connected to each of the extending parts 421b. Each of the extending parts 421b has a strip shape extending from the connecting part 421a in the first direction x. In plan view, the extending parts 421b are aligned in the second direction y and arranged in parallel to each other. Each of the extending parts 421b has a tip that overlaps with an insulating block member 429 in plan view. The tip is bonded to the block member 429 with a non-illustrated bonding material. The tip is an end of the extending part 421b in the first direction x, where the end is located opposite from the other end of the extending part 421b that is connected to the connecting part 421a. The method for bonding between the extending part 421b and the block member 429 is not limited to using a bonding material. For example, the bonding may be achieved by laser welding or ultrasonic bonding.

The power terminal 43 of the semiconductor device A4 has a bonding portion 431 electrically bonded to the conductive plate 34B. In the example shown in FIG. 22, a tip of the bonding portion 431 (the tip being located opposite from the base end that is connected to a terminal portion 432) has a comb-like shape, and this comb-like portion is electrically bonded to the conductive plate 34B. The method for bonding between the bonding portion 431 and the conductive plate 34B is not particularly limited. For example, the bonding may be achieved by any of laser bonding, ultrasonic bonding, or bonding with a conductive bonding member.

An insulating member 40 is electrically insulative, and is made of insulating paper, for example. As shown in FIGS. 4, 6, 9, 10, and 11, the insulating member 40 is sandwiched between the terminal portion 412 of the power terminal 41 and the terminal portion 422 of the power terminal 42 in the third direction z. The insulating member 40 insulates the two power terminals 41 and 42 from each other. A portion of the insulating member 40 (i.e., the portion in one sense of the first direction x) is covered with the sealing member 6.

The power connecting member 511 is bonded to the source 112 of the MOSFET 11 and the conductive plate 34B to electrically connect them. Each of the power connecting members 512 is bonded to the emitter 122 of an IGBT 12 and the conductive plate 34B to electrically connect them. The power connecting member 513 is bonded to an anode 131 of the SBD 13 and the conductive plate 34B to electrically connect them.

The power connecting member 521 is bonded to the source 212 of the MOSFET 21 and one of the extending parts 421b of the power terminal 42 to electrically connect them. Each of the power connecting members 522 is bonded to the emitter 222 of an IGBT 22 and one of the extending parts 421b of the power terminal 42 to electrically connect them. The power connecting member 523 is bonded to an anode 231 of the SBD 23 and one of the extending parts 421b of the power terminal 42 to electrically connect them.

The semiconductor device A4 is similar to the semiconductor devices A1 to A3 in that the element withstand voltage of the MOSFET 11 is larger than the element withstand voltage of each of the IGBTs 12. Accordingly, as with the semiconductor devices A1 to A3, the semiconductor device A4 can reduce failures caused by a surge voltage when the MOSFET 11 and the IGBTs 12 perform operations in parallel, and can suppress a decrease in reliability. In the semiconductor device A4, the element withstand voltage of the MOSFET 21 is larger than the element withstand voltage of each of the IGBTs 22. Accordingly, as with the semiconductor devices A1 to A3, the semiconductor device A4 can reduce failures caused by a surge voltage when the MOSFET 21 and the IGBTs 22 perform operations in parallel, and can suppress a decrease in reliability. Furthermore, the semiconductor device A4 has advantages similar to each of the semiconductor devices A1 to A3 owing to its common configuration with each of the semiconductor devices A1 to A3.

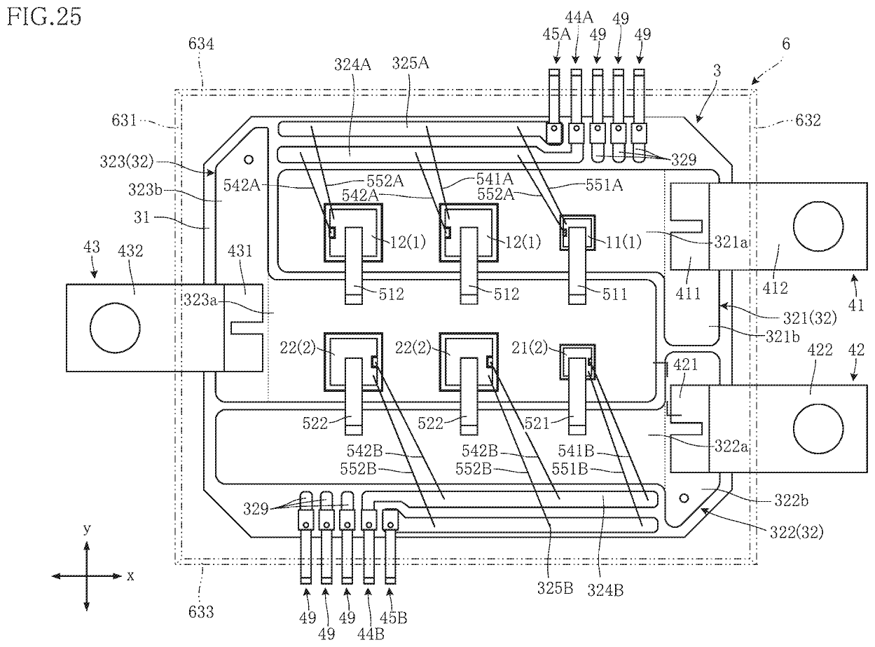

In the examples shown in the first embodiment to the fourth embodiment, the switching circuit 1 of each of the semiconductor devices A1 to A4 includes at least one MOSFET 11, at least one IGBT 12, and at least one SBD 13. However, the switching circuit 1 may not include the SBD 13 as long as the switching circuit 1 includes at least one MOSFET 11 and at least one IGBT 12. For example, FIG. 25 shows an example where the switching circuit 1 of the semiconductor device A1 includes a MOSFET 11 and two IGBTs 12. As can be understood from FIG. 25, the switching circuit 2 also has a similar configuration. Note that when the MOSFET 11 and the IGBTs 12 are operated in parallel, the MOSFET 11 is preferentially operated in a low current range, and the IGBTs 12 are preferentially operated in a high current range in order to reduce a power loss caused by on-resistance. In this regard, the operation load is lower in the low current range than in the high current range, while the operation load is higher in the high current range than in the low current range. Thus, in the semiconductor device shown in FIG. 25, the number of IGBTs 12, preferentially operated in the high current range, is larger than the number of MOSFETs 11, preferentially operated in the low current range.

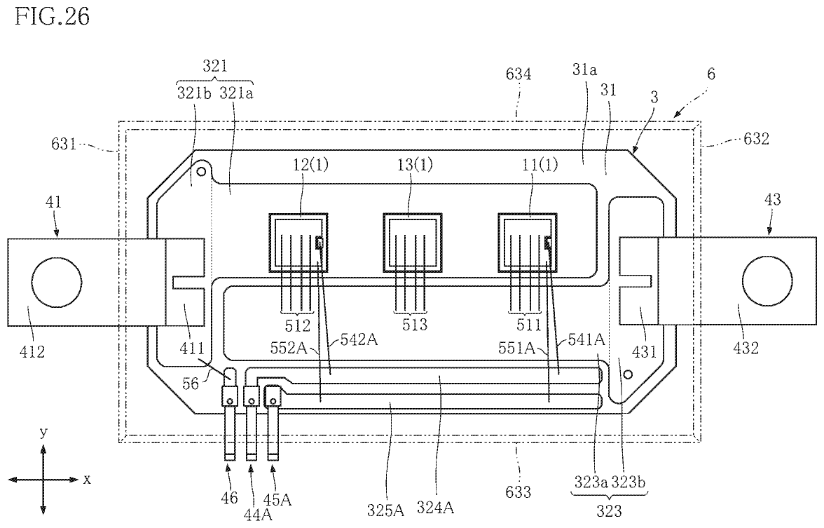

In the examples shown in the first embodiment to the fourth embodiment, each of the semiconductor devices A1 to A4 includes two switching circuits 1 and 2. However, each of the semiconductor devices A1 to A4 may include a single switching circuit 1. For example, FIG. 26 shows an example where the semiconductor device A1 includes a switching circuit 1 but not a switching circuit 2.

The semiconductor device according to the present disclosure is not limited to the foregoing embodiments. Various design changes can be made to the specific configurations of the elements of the semiconductor device according to the present disclosure. For example, the present disclosure includes embodiments described in the following clauses.

Clause 1.

A semiconductor device comprising:
a first MOSFET; and
a first IGBT,
wherein a drain of the first MOSFET and a collector of the first IGBT are electrically connected to each other,
a source of the first MOSFET and an emitter of the first IGBT are electrically connected to each other, and
an element withstand voltage of the first MOSFET is larger than an element withstand voltage of the first IGBT.

Clause 2.

The semiconductor device according to clause 1,
wherein the first MOSFET comprises SiC, and
the first IGBT comprises Si.

Clause 3.

The semiconductor device according to clause 1 or 2, further comprising:
a first power terminal electrically connected to the drain of the first MOSFET and the collector of the first IGBT; and
a second power terminal electrically connected to the source of the first MOSFET and the emitter of the first IGBT,
wherein an inductance of a first conduction path from the drain of the first MOSFET to the first power terminal is smaller than an inductance of a second conduction path from the collector of the first IGBT to the first power terminal.

Clause 4.

The semiconductor device according to clause 3, further comprising a first Schottky barrier diode electrically connected in parallel to the first MOSFET and the first IGBT.

Clause 5.

The semiconductor device according to clause 4, wherein the first Schottky barrier diode comprises SiC.

Clause 6.

The semiconductor device according to clause 4 or 5, wherein a third conduction path from the first Schottky barrier diode to the first power terminal is longer than the first conduction path and shorter than the second conduction path.

Clause 7.

The semiconductor device according to any of clauses 3 to 6, further comprising:
a second MOSFET; and
a second IGBT,
wherein a drain of the second MOSFET and a collector of the second IGBT are electrically connected to each other,
a source of the second MOSFET and an emitter of the second IGBT are electrically connected to each other, and
an element withstand voltage of the second MOSFET is larger than an element withstand voltage of the second IGBT.

Clause 8.

The semiconductor device according to clause 7,
wherein the second MOSFET comprises SiC, and
the second IGBT comprises Si.

Clause 9.

The semiconductor device according to clause 7 or 8, further comprising a third power terminal electrically connected to the source of the second MOSFET and the emitter of the second IGBT,
wherein the second power terminal is electrically connected to the drain of the second MOSFET and the collector of the second IGBT, and
an inductance of a fourth conduction path from the source of the second MOSFET to the first power terminal is smaller than an inductance of a fifth conduction path from the emitter of the second IGBT to the first power terminal.

Clause 10.

The semiconductor device according to clause 9, further comprising a second Schottky barrier diode electrically connected in parallel to the second MOSFET and the second IGBT.

Clause 11.

The semiconductor device according to clause 10, wherein the second Schottky barrier diode comprises SiC.

Clause 12.

The semiconductor device according to clause 10 or 11, wherein a sixth conduction path from the second Schottky barrier diode to the first power terminal is longer than the fourth conduction path and shorter than the fifth conduction path.

Clause 13.

The semiconductor device according to any of clauses 9 to 12, further comprising:
a first conductor to which the first power terminal is connected;
a second conductor to which the second power terminal is connected; and
a third conductor to which the third power terminal is connected,
wherein the first conductor includes a first pad portion electrically connected to the drain of the first MOSFET and the collector of the first IGBT,
the second conductor includes a second pad portion electrically connected to the source of the first MOSFET, the emitter of the first IGBT, the drain of the second MOSFET, and the collector of the second IGBT, and
the third conductor includes a third pad portion electrically connected to the source of the second MOSFET and the emitter of the second IGBT.

Clause 14.

The semiconductor device according to clause 13, wherein each of the first MOSFET and the second MOSFET has a vertical structure in which the drain and the source are spaced apart from each other in a thickness direction thereof, and
each of the first IGBT and the second IGBT has a vertical structure in which the collector and the emitter are spaced apart from each other in a thickness direction thereof.

Clause 15.

The semiconductor device according to clause 14, further comprising:
a first connecting member that electrically connects the source of the first MOSFET and the second pad portion; and
a second connecting member that electrically connects the emitter of the first IGBT and the second pad portion,
wherein the drain of the first MOSFET and the collector of the first IGBT are electrically bonded to the first pad portion.

Clause 16.

The semiconductor device according to clause 15, further comprising:
a third connecting member that electrically connects the source of the second MOSFET and the third pad portion; and
a fourth connecting member that electrically connects the emitter of the second IGBT and the third pad portion,
wherein the drain of the second MOSFET and the collector of the second IGBT are electrically bonded to the second pad portion.

Clause 17.

The semiconductor device according to clause 16, wherein the first MOSFET and the first IGBT are arranged in a first arrangement direction intersecting with a thickness direction of the first pad portion,
the second MOSFET and the second IGBT are arranged in a second arrangement direction intersecting with a thickness direction of the second pad portion, and
the first arrangement direction and the second arrangement direction are the same direction.

Clause 18.

The semiconductor device according to clause 17, wherein the first power terminal and the third power terminal are located opposite from the first IGBT with respect to the first MOSFET in the first arrangement direction, and are located opposite from the second IGBT with respect to the second MOSFET in the second arrangement direction.

### REFERENCE SIGNS

A1 to A4: Semiconductor device 1, 2: Switching circuit
11, 21: MOSFET 11a, 21a: Obverse surface
11b, 21b: Reverse surface 111, 211: Drain
112, 212: Source 113, 213: Gate
12, 22: IGBT 12a, 22a: Obverse surface
12b, 22b: Reverse surface 121, 221: Collector
122, 222: Emitter 123, 223: Gate
13, 23: SBD 13a, 23a: Obverse surface
13b, 23b: Reverse surface 131, 231: Anode
132, 232: Cathode 3: Supporting member
31: Insulating substrate 31a: Obverse surface
31b: Reverse surface 311, 312: Through hole
313, 314: Opening 32: Obverse-surface metal layer
321, 322, 323: Power wiring section 321a, 321b: Pad portion
322a, 322b: Pad portion 322s: Slit
323a, 323b: Pad portion 323c: Through hole
324A, 324B: Signal wiring section
325A, 325B: Signal wiring section
326, 327, 329: Signal wiring section 326a: Through hole
33: Reverse-surface metal layer
331, 332: Power wiring section
331a, 332a: Opening 331b, 332b: Through hole
34A, 34B: Conductive plate 35, 35A, 35B: Insulating plate
36A, 36B: Insulating plate 371A, 371B: Signal wiring section
372A, 372B: Signal wiring section 391, 392: Metal member
40: Insulating member 41, 42, 43: Power terminal
411, 421, 431: Bonding portion
412, 422, 432: Terminal portion
421a: Connecting part 421b: Extending part
429: Block member 44A, 44B: Signal terminal
45B: Signal terminal 46, 47, 49: Signal terminal
511, 512, 513, 521, 522, 523: Power connecting member
540A, 540B, 541A, 541B, 542A, 542B: Signal connecting member
550A, 550B, 551A, 551B, 552A, 552B: Signal connecting member
56, 57: Signal connecting member 6: Sealing member
61: Resin obverse surface 62: Resin reverse surface
631 to 634: Resin side surface 70: Heat dissipating plate
71: Case 72: Frame
73: Top plate 741 to 744: Terminal block
75: Resin member TH: Thermistor

1. A semiconductor device comprising:
a first MOSFET; and
a first IGBT,
wherein a drain of the first MOSFET and a collector of the first IGBT are electrically connected to each other,
a source of the first MOSFET and an emitter of the first IGBT are electrically connected to each other, and
an element withstand voltage of the first MOSFET is larger than an element withstand voltage of the first IGBT.

2. The semiconductor device according to claim 1,
wherein the first MOSFET comprises SiC, and
the first IGBT comprises Si.

3. The semiconductor device according to claim 1, further comprising:
a first power terminal electrically connected to the drain of the first MOSFET and the collector of the first IGBT; and
a second power terminal electrically connected to the source of the first MOSFET and the emitter of the first IGBT,
wherein an inductance of a first conduction path from the drain of the first MOSFET to the first power terminal is smaller than an inductance of a second conduction path from the collector of the first IGBT to the first power terminal.

4. The semiconductor device according to claim 3, further comprising a first Schottky barrier diode electrically connected in parallel to the first MOSFET and the first IGBT.

5. The semiconductor device according to claim 4, wherein the first Schottky barrier diode comprises SiC.

6. The semiconductor device according to claim 4, wherein a third conduction path from the first Schottky barrier diode to the first power terminal is longer than the first conduction path and shorter than the second conduction path.

7. The semiconductor device according to claim 3, further comprising:
a second MOSFET; and
a second IGBT,
wherein a drain of the second MOSFET and a collector of the second IGBT are electrically connected to each other,
a source of the second MOSFET and an emitter of the second IGBT are electrically connected to each other, and
an element withstand voltage of the second MOSFET is larger than an element withstand voltage of the second IGBT.

8. The semiconductor device according to claim 7,
wherein the second MOSFET comprises SiC, and
the second IGBT comprises Si.

9. The semiconductor device according to claim 7, further comprising a third power terminal electrically connected to the source of the second MOSFET and the emitter of the second IGBT,
wherein the second power terminal is electrically connected to the drain of the second MOSFET and the collector of the second IGBT, and
an inductance of a fourth conduction path from the source of the second MOSFET to the first power terminal is smaller than an inductance of a fifth conduction path from the emitter of the second IGBT to the first power terminal.

10. The semiconductor device according to claim 9, further comprising a second Schottky barrier diode electrically connected in parallel to the second MOSFET and the second IGBT.

11. The semiconductor device according to claim 10, wherein the second Schottky barrier diode comprises SiC.

12. The semiconductor device according to claim 10, wherein a sixth conduction path from the second Schottky barrier diode to the first power terminal is longer than the fourth conduction path and shorter than the fifth conduction path.

13. The semiconductor device according to claim 9, further comprising:
a first conductor to which the first power terminal is connected;
a second conductor to which the second power terminal is connected; and
a third conductor to which the third power terminal is connected,
wherein the first conductor includes a first pad portion electrically connected to the drain of the first MOSFET and the collector of the first IGBT,
the second conductor includes a second pad portion electrically connected to the source of the first MOSFET, the emitter of the first IGBT, the drain of the second MOSFET, and the collector of the second IGBT, and
the third conductor includes a third pad portion electrically connected to the source of the second MOSFET and the emitter of the second IGBT.

14. The semiconductor device according to claim 13, wherein each of the first MOSFET and the second MOSFET has a vertical structure in which the drain and the source are spaced apart from each other in a thickness direction thereof, and
each of the first IGBT and the second IGBT has a vertical structure in which the collector and the emitter are spaced apart from each other in a thickness direction thereof.

15. The semiconductor device according to claim 14, further comprising:
a first connecting member that electrically connects the source of the first MOSFET and the second pad portion; and
a second connecting member that electrically connects the emitter of the first IGBT and the second pad portion,
wherein the drain of the first MOSFET and the collector of the first IGBT are electrically bonded to the first pad portion.

16. The semiconductor device according to claim 15, further comprising:
a third connecting member that electrically connects the source of the second MOSFET and the third pad portion; and
a fourth connecting member that electrically connects the emitter of the second IGBT and the third pad portion,
wherein the drain of the second MOSFET and the collector of the second IGBT are electrically bonded to the second pad portion.

17. The semiconductor device according to claim 16, wherein the first MOSFET and the first IGBT are arranged in a first arrangement direction intersecting with a thickness direction of the first pad portion,
the second MOSFET and the second IGBT are arranged in a second arrangement direction intersecting with a thickness direction of the second pad portion, and
the first arrangement direction and the second arrangement direction are the same direction.

18. The semiconductor device according to claim 17, wherein the first power terminal and the third power terminal are located opposite from the first IGBT with respect to the first MOSFET in the first arrangement direction, and are located opposite from the second IGBT with respect to the second MOSFET in the second arrangement direction.
